(19) United States
(12) Patent Application Publication
(10) Pub. No.: US 2025/0007580 A1
(43) Pub. Date: Jan. 2, 2025

(54) METHODS AND APPARATUS TO FORM AN IMAGE WITH DYNAMIC DELAY AND GAIN BEAMFORMING

(71) Applicant: Texas Instruments Incorporated, Dallas, TX (US)

(72) Inventors: Vajeed Nimran, Bangalore (IN); Sachin Aithal, Bangalore (IN); Shabbir Amjhera Wala, Bangalore (IN); Rahul Reji, Bangalore (IN)

(21) Appl. No.: 18/755,227

(22) Filed: Jun. 26, 2024

(30) Foreign Application Priority Data
Jun. 27, 2023 (IN) 202341042905

(51) Int. Cl. H04B 7/06

(52) U.S. Cl. CPC H04B 7/0617; H04B 7/0667

(57) ABSTRACT

An example apparatus includes: at least one memory; programmable circuitry; and machine readable instructions to cause the programmable circuitry to at least: determine beamforming delay profiles for a plurality of channels, the beamforming delay profiles including delay values corresponding to a distance from a channel for a beamline; split the beamforming delay profiles into a plurality of segments; fit the plurality of segments of the beamforming delay profiles to linear segments; generate piece-wise beamforming delay profiles including initial values of the beamforming delay profiles, slopes of the linear segments of the plurality of segments, and durations of the plurality of segments; and store the piece-wise beamforming delay profiles for beamforming.

### CROSS-REFERENCE TO RELATED APPLICATION

This patent application claims the benefit of and priority to Indian Provisional Patent Application No. 202341042905 filed Jun. 27, 2023, which is hereby incorporated herein by reference in its entirety.

### TECHNICAL FIELD

This description relates generally to beamforming and, more particularly, to methods and apparatus to form an image with dynamic delay and gain beamforming.

### BACKGROUND

In beamforming circuitry, increasingly complex beamforming operations allow systems to support higher quality imaging and higher operating speeds. Such operations allow the beamforming circuitry to accurately support a wide range of imaging operations.

### SUMMARY

For methods and apparatus to form an image with dynamic delay and gain beamforming, an example apparatus includes at least one memory; programmable circuitry; and machine readable instructions to cause the programmable circuitry to at least: determine beamforming delay profiles for a plurality of channels, the beamforming delay profiles including delay values corresponding to a distance from a channel for a beamline; split the beamforming delay profiles into a plurality of segments; fit the plurality of segments of the beamforming delay profiles to linear segments; generate piece-wise beamforming delay profiles including initial values of the beamforming delay profiles, slopes of the linear segments of the plurality of segments, and durations of the plurality of segments; and store the piece-wise beamforming delay profiles for beamforming. Other examples are described.

For methods and apparatus to form an image with dynamic delay and gain beamforming, an example apparatus includes at least one memory; programmable circuitry; and machine readable instructions to cause the programmable circuitry to: determine a reference gain profile, the reference gain profile including gain values corresponding to a distance of a focus point from a channel; determine an expansion profile for the reference gain profile; split the expansion profile into a plurality of segments; fit the plurality of segments of the expansion profile to linear segments; generate a piece-wise expansion profile including an initial value of the expansion profile, slopes of the linear segments of the plurality of segments, and durations of the plurality of segments; and store the piece-wise expansion profile for beamforming. Other examples are described.

For methods and apparatus to form an image with dynamic delay and gain beamforming, an example at least one non-transitory machine-readable storage medium including instructions that at least generate piece-wise delay profiles including initial values of beamforming delay profiles, slopes of first linear segments of a first plurality of segments of the beamforming delay profiles, and durations of the first plurality of segments, the beamforming delay profiles including delay values corresponding to a distance from a channel for a beam line; and generate a piece-wise expansion profile including an initial value of an expansion profile of a reference gain profile, slopes of second linear segments of a second plurality of segments of the expansion profile, and durations of the second plurality of segments, the reference gain profile including gain values corresponding to a distance of a focus point from a channel. Other examples are described.

### BRIEF DESCRIPTION OF THE DRAWINGS

FIG. 1 is a block diagram of an example ultrasound system including example analog front-end circuitry having example beamforming circuitry, which constructs an image using beamforming.

FIG. 2 is an example of the image of FIG. 1.

FIG. 3A is an example of continuous delay profiles of the image of FIG. 2.

FIG. 3B is an example of piecewise delay profiles of the continuous delay profiles of FIG. 3A.

FIG. 4A is an example of gain profiles of the image of FIG. 2.

FIG. 4B is an example reference apodization profile of the image of FIG. 2.

FIG. 5A is an example continuous expansion profile of the reference gain profile of FIG. 4B.

FIG. 5B is an example piecewise expansion profile of the continuous expansion profile of FIG. 5A.

FIG. 6 is a block diagram of example piecewise beamforming compiler circuitry which generates the piecewise delay profiles of FIG. 3B and the piecewise expansion profile of FIG. 5B for beamforming.

FIG. 7 is a flowchart representative of example machine-readable instructions or example operations that may be at least one of executed, instantiated, or performed using an example programmable circuitry implementation of the piecewise beamforming compiler circuitry of FIG. 6.

FIG. 8 is a flowchart representative of example machine-readable instructions or example operations that may be at least one of executed, instantiated, or performed using an example programmable circuitry implementation of the piecewise beamforming compiler circuitry of FIG. 6 to generate the continuous delay profiles of FIG. 3A.

FIG. 9 is a flowchart representative of example machine-readable instructions or example operations that may be at least one of executed, instantiated, or performed using an example programmable circuitry implementation of the piecewise beamforming compiler circuitry of FIG. 6 to generate the piecewise delay profiles of FIG. 3B.

FIG. 10 is a flowchart representative of example machine-readable instructions or example operations that may be at least one of executed, instantiated, or performed using an example programmable circuitry implementation of the piecewise beamforming compiler circuitry of FIG. 6 to generate the piecewise expansion profile of FIG. 5B.

FIG. 11 is a block diagram of an example of the analog front-end circuitry of FIG. 1 including an example of the beamforming circuitry of FIG. 1.

FIG. 12 is a block diagram of an example of the beamforming circuitry of FIGS. 1 and 11 including example beamforming control circuitry.

FIG. 13 is a flowchart representative of example machine-readable instructions or example operations that may be at least one of executed, instantiated, or performed using an example programmable circuitry implementation of the beamforming circuitry of FIGS. 1, 11, and 12.

FIG. 14 is a flowchart representative of example machine-readable instructions or example operations that may be at least one of executed, instantiated, or performed using an example programmable circuitry implementation of the beamforming circuitry of FIGS. 1, 11, and 12 to determine delay values from the piecewise profiles of FIG. 3B.

FIG. 15 is a flowchart representative of example machine-readable instructions or example operations that may be at least one of executed, instantiated, or performed using an example programmable circuitry implementation of the beamforming circuitry of FIGS. 1, 11, and 12 to determine gain values from the reference apodization profile of FIG. 4B and the piecewise profile of FIG. 5B.

FIG. 16 is a block diagram of an example processing platform including programmable circuitry structured to execute, instantiate, or perform the example machine-readable instructions or perform the example operations of FIGS. 7, 8, 9, 10, 13, 14, and/or 15.

FIG. 17 is a block diagram of an example implementation of the programmable circuitry of FIG. 16.

FIG. 18 is a block diagram of another example implementation of the programmable circuitry of FIG. 16.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

In beamforming circuitry, increasingly complex beamforming operations allow systems to support higher quality imaging and higher operating speeds. Such operations allow the beamforming circuitry to accurately support a wide range of imaging operations.

In ultrasound imaging, transmitter circuitry excites one or more transducers to generate signals that traverse a medium being imaged. The medium generates reflected signals as the transmitted signals propagate through the medium. In response to the reflected signals, the transducers generate analog signals representative of the reflected signals exciting the transducers. Such a process of transmitting signals and receiving reflected signals allows systems to generate images that are not observable by a traditional image capture system, such as a camera. In ultrasound imaging systems, analog front-end (AFE) circuitry converts the analog values of the analog signals to digital signals to reduce processing complexity.

Beamforming allows imaging systems to generate an image of internal components of a medium using the reflected signals. Beamforming is a process of combining values of the reflected signals from the transducers to determine a value of a focus point in an image. To generate an image using beamforming, imaging systems divide an image into a series of beamlines that are perpendicular to the transducers and span an x-axis of the image. The imaging systems further divide the image by positioning focus points along the beamlines and spanning a y-axis. The focus points have coordinates in an image similar to pixels. However, the x-axis coordinate of a focus point corresponds to a location in relation to a position of the transducers and y-axis coordinate corresponds to an image depth. Some systems designate a position of one of the transducers to be an origin location for images. The position of the selected transducer corresponds to a minimum image depth and provides a reference location for the x-axis coordinates. In operation, programmable circuitry generates an image by performing specific beamforming operations for the focus points comprising the image.

To generate a value representative of a focus point on a specific beamline and at a specific image depth, the programmable circuitry individually delays the reflected signals from the transducers. The programmable circuitry determines a delay value based on a position of the focus point in the image and which of the transducers are supplying the reflected signal. In beamforming, delaying the signals from the transducers allows the programmable circuitry to account for different propagation times of the reflected signal through the medium. For example, a focus point having a first distance to a first transducer also has a second distance to a second transducer. In such examples, supplying a first delay value to the signal from the first transducer and a second delay value to the signal from the second transducers allows the beamforming operations to account for the difference between the first and second distances. After delaying the reflected signals, the timing of the reflected signals accounts for propagation delays of reflected signals.

Before combining the values of the retimed reflected signals, the programmable circuitry individually amplifies the retimed reflected signals based on the location of the transducer and the image depth of the focus point. Such a process of amplifying the retimed reflected signals is referred to as apodization. The programmable circuitry determines a gain value based on the position of the focus point in relation to the transducer corresponding to the retimed reflected signal. In beamforming, amplifying the retimed reflected signals accounts for a spatial location of a focus point in relation to the transducers. The gain values compensate the retimed reflected signals for an amount of noise resulting from different focus point locations. For example, a first retimed reflected signal has a first gain value and a second retimed signal has a second gain value. The second gain value is less than the first gain value, responsive to the focus point being spatially closer to a first transducer of the first retimed reflected signal. In such examples, the position of the first transducer results in less noise than a position of a second transducer of the second retimed reflected signal. As the image depth increases, the positioning of the transducers in relation to the focus point begin to converge, which decreases the variation in gain values across the retimed reflected signals.

To complete beamforming operations for a focus point, the programmable circuitry combines the amplified and retimed reflected signals of the transducers to generate a value of a focus point in the medium. The programmable circuitry performs retiming and amplifying beamforming operations to the focus points of the beamlines to generate an image of the medium. To completely form an image using beamforming, the programmable circuitry uses a different gain and delay value for each of the focus points, each of the beamlines, and each of the transducers of the imaging system. As imaging systems continue to support higher imaging speeds, higher resolutions, and an increasing number of transducers, the amount of delay and gain values needed to implement beamforming to produce an image continues to increase.

Examples described herein include methods and apparatus to form an image with dynamic delay and gain beamforming. In some described examples, an example imaging system includes transmitter circuitry, a plurality of transducer channels, and AFE circuitry. The AFE circuitry further includes example ADC circuitry, example beamforming circuitry, and example beamforming control circuitry. The transmitter circuitry uses one or more of the plurality of transducer channels to transmit a signal into a medium for imaging. The transducer channels generate analog signals responsive to receiving reflected signals from the medium. The ADC circuitry converts the analog signals into digital signals representing the reflected signals. The beamforming circuitry delays, amplifies, and combines the reflected signals responsive to receiving delay values and gain values from the beamforming control circuitry. The beamforming circuitry supplies the determined focus point values to programmable circuitry, which facilitates displaying the formed image to a user.

In the described examples, the beamforming control circuitry determines the delay values and the gain values for a selected focus point and a selected beamline based on piecewise delay profiles, a reference apodization profile, and a piecewise expansion profile. The piecewise delay profiles are a series of linear segments that represent the delay values of a transducer channel for focus points of a specific beamline. In some examples, the piecewise delay profiles include an initial delay value, a duration, and a slope of the segments. In example operations, the beamforming control circuitry determines delay values of a selected focus point based on the initial delay value and an accumulation of previous delay values. The rate of the accumulation of previous delay values is set by the slope of the segment containing the selected focus point.

The reference apodization profile is a plurality of gains of the transducer channels for focus points having a reference image depth. The reference apodization profile may correspond to focus points of different beamlines by shifting a peak gain value to the selected beamline. The piecewise expansion profile is a series of linear segments that represent an expansion factor of the reference apodization profile based on an image depth of the selected focus point. In some example operations, when the focus point has an image depth less than the reference image depth of the reference apodization profile, the beamforming control circuitry determines an expansion factor to compress the reference apodization profile. In such examples, the beamforming control circuitry determines relatively high gain values for transducer channels closest to the selected focus point and relatively low gain values for transducer channels farthest from the selected focus point. In other example operations, when the focus point has an image depth approaching a maximum image depth, the beamforming control circuitry determines an expansion factor, which expands the reference apodization profile. In such examples, the determined gain values of the transducer channels begin to converge as the noise resulting from different propagation distances converges.

Advantageously, using piecewise delay profiles reduces the amount of data needed to determine delay values for focus points that form an image. Advantageously, using a reference apodization profile and expansion factor to expand and compress gain values reduces the amount of data needed to determine gain values for focus points that form an image. Advantageously, using the piecewise expansion profile reduces the amount of data needed to determine the expansion factor of the reference apodization profile. Advantageously, implementing the beamforming circuitry in the AFE circuitry reduces the complexity of programmable circuitry and reduces the number of external connections between the AFE circuitry and the programmable circuitry.

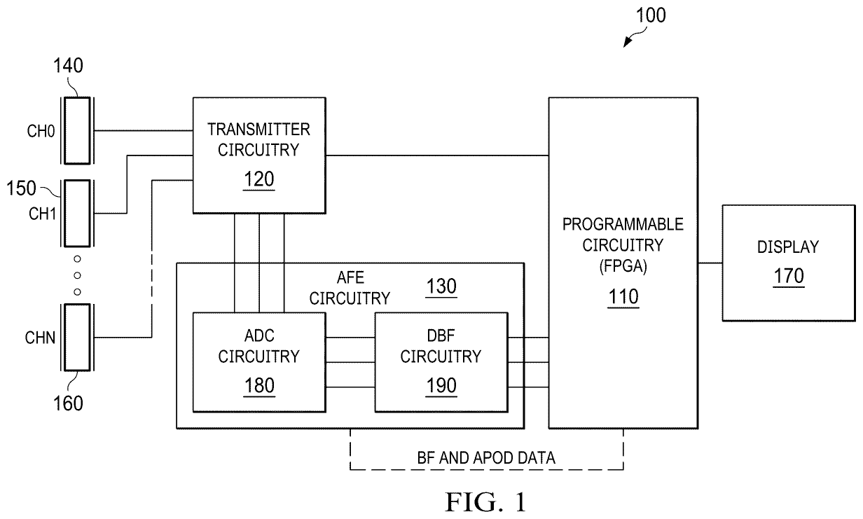

FIG. 1 is a block diagram of an example ultrasound system 100. In the example of FIG. 1, the ultrasound system 100 includes programmable circuitry 110, transmitter circuitry 120, analog front-end (AFE) circuitry 130, a first transducer channel 140, a second transducer channel 150, a third transducer channel 160, and a display 170. The example AFE circuitry 130 of FIG. 1 includes example analog-to-digital converter (ADC) circuitry 180 and example beamforming circuitry 190. In some examples, the ultrasound system 100 may be illustrated or described as a radar system or alternative type of beamforming based imaging system.

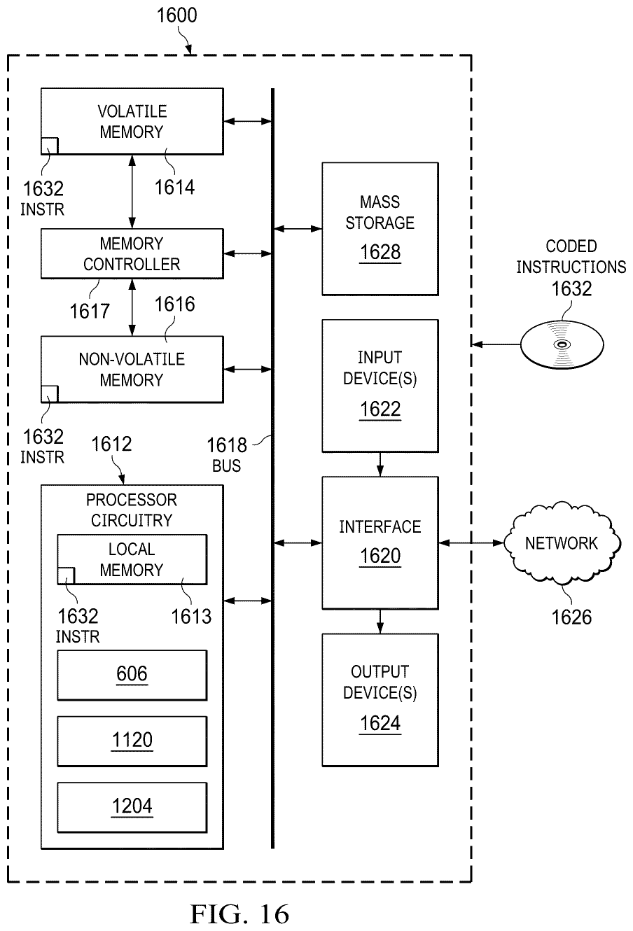

The programmable circuitry 110 has a first terminal, a second terminal, a third terminal, a fourth terminal, a fifth terminal, and may have a sixth terminal. The first terminal of the programmable circuitry 110 is coupled to the transmitter circuitry 120. The second, third, and fourth terminals of the programmable circuitry 110 are coupled to the AFE circuitry 130. The fifth terminal of the programmable circuitry 110 is coupled to the display 170. In some examples, the programmable circuitry 110 is communicatively coupled to the display 170 using interface circuitry. In such examples, the interface circuitry implements one or more communication protocols to communicate with the display 170. For example, the programmable circuitry 110 uses a wireless communication protocol (e.g., Bluetooth) to communicate with the display 170. The sixth terminal of the programmable circuitry 110 is coupled to the AFE circuitry 130. In the example of FIG. 1, the programmable circuitry 110 is described as field programmable gate array (FPGA) circuitry. Alternatively, the programmable circuitry 110 may be any type of circuitry structured to instantiate circuitry to perform operations corresponding to executing machine-readable instructions. Some such examples are further described and illustrated below in connection with FIGS. 16, 17, and 18.

The transmitter circuitry 120 has a first terminal, a second terminal, a third terminal, a fourth terminal, a fifth terminal, a sixth terminal, and a seventh terminal. The first terminal of the transmitter circuitry 120 (also referred to as an input terminal) is coupled to the programmable circuitry 110. The second, third, and fourth terminals of the transmitter circuitry 120 (also referred to as output terminals) are coupled to the AFE circuitry 130. The fifth terminal of the transmitter circuitry 120 is coupled to the transducer channel 140. The sixth terminal of the transmitter circuitry 120 is coupled to the transducer channel 150. The seventh terminal of the transmitter circuitry 120 is coupled to the transducer channel 160.

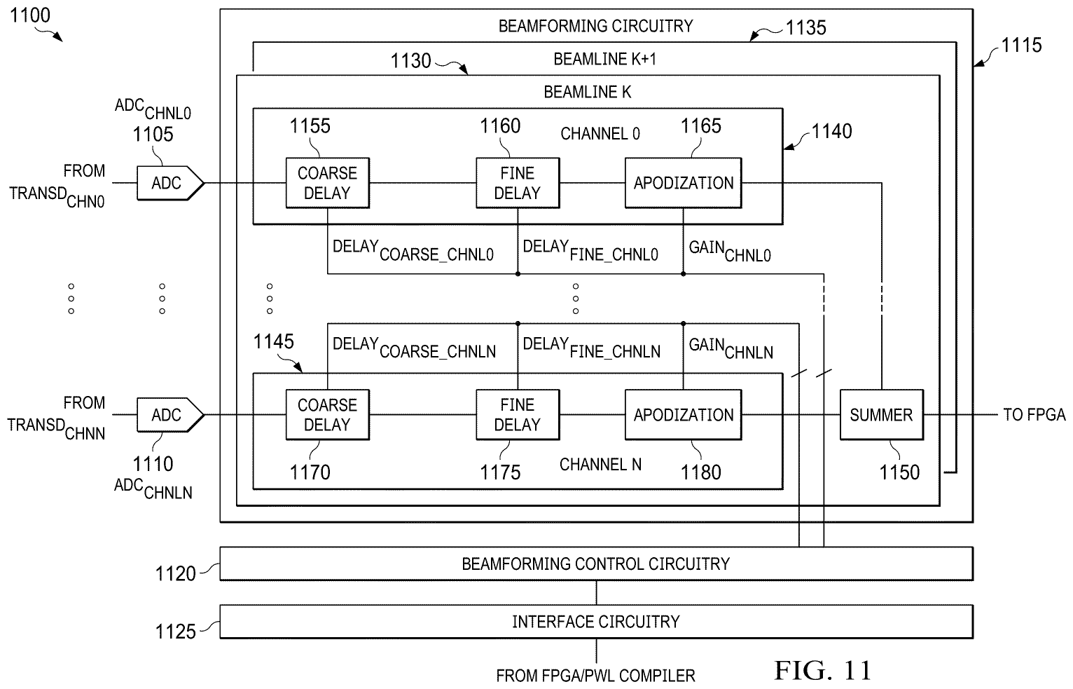

The AFE circuitry 130 has a first terminal, a second terminal, a third terminal, a fourth terminal, a fifth terminal, and a sixth terminal. The first, second, and third terminals of the AFE circuitry 130 (also referred to as input terminals) are coupled to the transmitter circuitry 120. The fourth, fifth, and sixth terminals of the AFE circuitry 130 are coupled to the programmable circuitry 110. In some examples, the AFE circuitry 130 has a seventh terminal coupled to the programmable circuitry 110. In such examples, the programmable circuitry 110 supplies gain and delay values to the AFE circuitry 130. An example of the AFE circuitry 130 is further illustrated and described in connection with FIG. 11, below.

The transducer channel 140 has a terminal coupled to the transmitter circuitry 120. In the example of FIG. 1, the transducer channel 140 forms a first channel (CH0) of the ultrasound system 100. The transducer channel 150 has a terminal coupled to the transmitter circuitry 120, the transducer channel 150 forms a second channel (CH1) of the ultrasound system 100. The transducer channel 160 has a terminal coupled to the transmitter circuitry 120. In the example of FIG. 1, the transducer channel 160 forms a final channel (CHN) of the ultrasound system 100. In the example of FIG. 1, the ultrasound system 100 has three transducer channels. In other examples, the ultrasound system 100 may be modified to have any number of channels. For example, the ultrasound system 100 may have one-hundred and twenty-eight channels to support higher resolution imaging. In such examples, the ultrasound system 100 has one-hundred and twenty-eight transducers. Also, the transducer channels 140, 150, 160 are positioned to transmit and receive signals through a medium being imaged by the ultrasound system 100.

The display 170 has a terminal coupled to the programmable circuitry 110. In some examples, the display 170 is illustrated or described as an external device. For example, when the programmable circuitry 110 is structured to use a wireless communication protocol to interface with the display 170, the display 170 may be an external device, such as a smartphone, tablet, screen, etc.

The ADC circuitry 180 has a first terminal, a second terminal, a third terminal, a fourth terminal, a fifth terminal, and a sixth terminal. The first, second, and third terminals of the ADC circuitry 180 (also referred to as input terminals) are coupled to the transmitter circuitry 120. The fourth, fifth, and sixth terminal of the ADC circuitry 180 are coupled to the beamforming circuitry 190. In the example of FIG. 1, the ADC circuitry 180 has a plurality of connections to support a plurality of analog-to-digital conversions. In some examples, the ADC circuitry 180 has additional connections to the beamforming circuitry 190 to support additional transducers. An example of the ADC circuitry 180 is further illustrated and described in connection with FIG. 11, below.

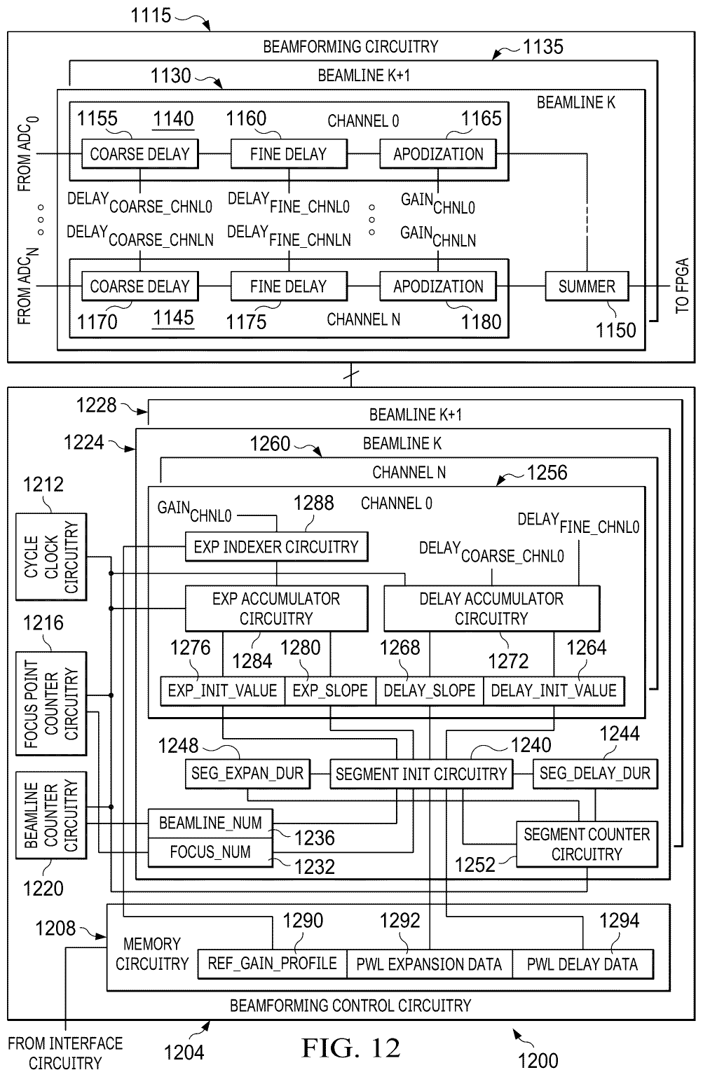

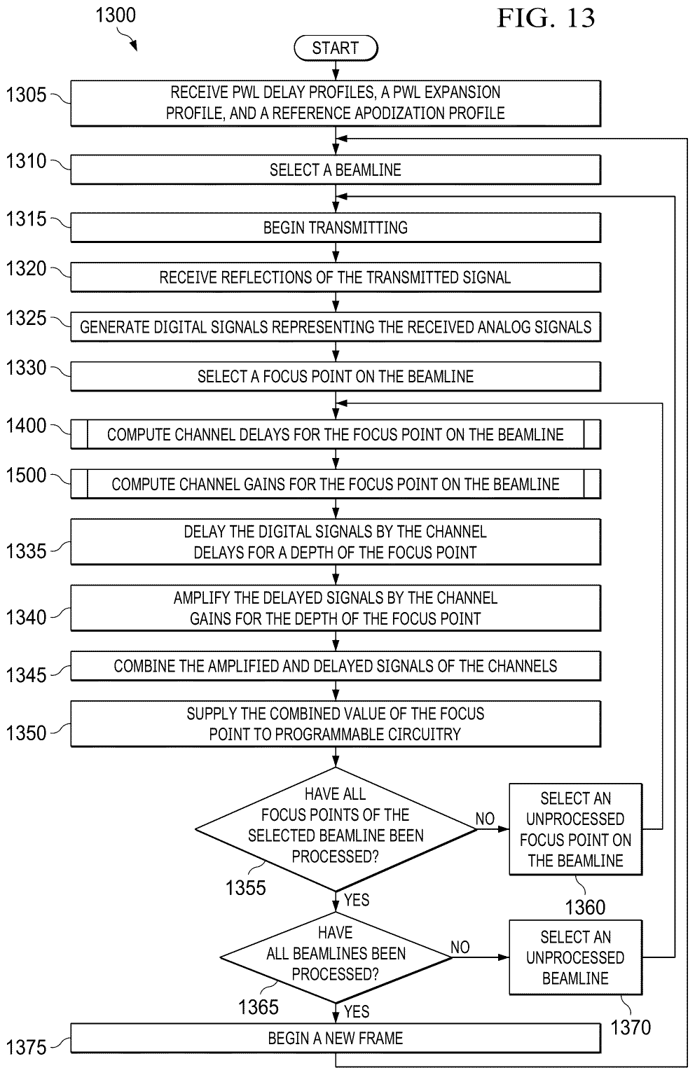

The beamforming circuitry 190 has a first terminal, a second terminal, a third terminal, a fourth terminal, a fifth terminal, and a sixth terminal. The first, second, and third terminals of the beamforming circuitry 190 are coupled to the ADC circuitry 180. The fourth, fifth, and sixth terminals of the beamforming circuitry 190 are coupled to the programmable circuitry 110. In some examples, the beamforming circuitry 190 has a seventh terminal coupled to the programmable circuitry 110, which supplies piecewise delay profiles, the reference apodization profile, and the piecewise expansion profile. Examples of the beamforming circuitry 190 are further illustrated and described in connection with FIGS. 11 and 12, below. Example operations of the ultrasound system 100 are illustrated and described in connection with FIGS. 13, 14, and 15, below.

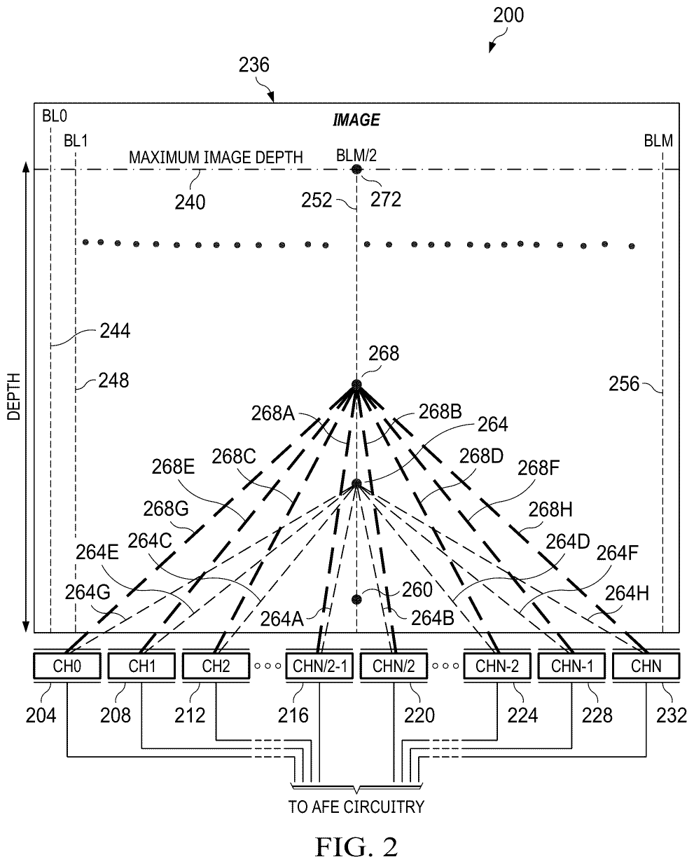

FIG. 2 illustrates an example imaging interface 200. In the example of FIG. 2, the imaging interface 200 includes a first transducer channel 204 (CH0), a second transducer channel 208 (CH1), a third transducer channel 212 (CH2), a fourth transducer channel 216 (CHN/2-1), a fifth transducer channel 220 (CHN/2), a sixth transducer channel 224 (CHN-2), a seventh transducer channel 228 (CHN-1), an eighth transducer channel 232 (CHN), and an image 236. The example image 236 of FIG. 2 includes an example maximum image depth 240, a first example beamline 244 (BL0), a second example beamline 248 (BL1), a third example beamline 252 (BLM/2), a fourth example beamline 256 (BLM), a first example focus point 260, a second example focus point 264, a third example focus point 268, and a fourth example focus point 272.

The imaging interface 200 represents positioning of the transducer channels 204, 208, 212, 216, 220, 224, 228, 232 to form the image 236 of a medium. The transducer channels 204, 208, 212, 216, 220, 224, 228, 232 are another example of the transducer channels 140, 150, 160 of FIG. 1 in the ultrasound system 100 of FIG. 1. The transducer channels 204, 208, 212, 216, 220, 224, 228, 232 are structured to transmit a signal responsive to the transmitter circuitry 120 of FIG. 1 exciting one or more of the transducer channels 204, 208, 212, 216, 220, 224, 228, 232. In some examples, the transmitter circuitry 120 excites one or more of the transducer channels 204, 208, 212, 216, 220, 224, 228, 232 to transmit a signal from a specific location. For example, the transmitter circuitry 120 may excite the transducer channels 216, 220 during beamforming operations of the beamline 252. In the example of FIG. 2, the imaging interface 200 includes the transducer channels 204, 208, 212, 216, 220, 224, 228, 232. In other examples, the imaging interface 200 may include any number of transducers to support any number of channels (N).

The image 236 represents a portion of a medium that the transducer channels 204, 208, 212, 216, 220, 224, 228, 232 are positioned to transmit signals into. In ultrasound systems, the image 236 is of the portion of the medium positioned in proximity to the transducer channels 204, 208, 212, 216, 220, 224, 228, 232. In such systems, the depth of the image 236 represents different internal portions of the medium.

The maximum image depth 240 represents a maximum depth of the image 236 into a given medium. In some examples, the maximum image depth 240 is set by a distance that the transmitted signal is capable of propagating through. In such examples, adjusting the power of the transmitted signal through the medium adjusts the maximum image depth 240.

The beamlines 244, 248, 252, 256 span from a minimum image depth at the transducer channels 204, 208, 212, 216, 220, 224, 228, 232 to the maximum image depth 240. The beamlines 244, 248, 252, 256 correspond to different locations across the transducer channels 204, 208, 212, 216, 220, 224, 228, 232. For example, the beamline 244 represents the left most portions of the image 236 and the beamline 256 represents the right most portions of the image 236. In the example of FIG. 2, the image 236 includes the beamlines 244, 248, 252, 256. In other examples, the image 236 may include any number of beamlines (M).

The focus points 260, 264, 268, 272 are different locations along the beamline 252 at which the beamforming circuitry 190 is structured to perform beamforming operations. In the example of FIG. 2, the beamline 252 includes the focus points 260, 264, 268, 272. In other examples, the beamlines 244, 248, 252, 256 may include any number of focus points. For example, the beamlines 244, 248, 252, 256 may individually have ten-thousand focus points spanning from a location closest to the transducer channels 204, 208, 212, 216, 220, 224, 228, 232 to the maximum image depth 240. Advantageously, increasing the number of the focus points 260, 264, 268, 272 across the beamlines 244, 248, 252, 256 increases the quality of the image 236.

In example beamforming operations of the focus point 264, the beamforming circuitry 190 uses different delay values for the transducer channels 204, 208, 212, 216, 220, 224, 228, 232 to determine a value at the focus point 264 on the beamline 252. The delay values of the beamforming circuitry 190 correspond to the distance between the transducer channels 204, 208, 212, 216, 220, 224, 228, 232 and the focus point 264. In the example of FIG. 2, the transducer channel 216 is a first distance 264A from the focus point 264, the transducer channel 220 is a second distance 264B from the focus point 264, the transducer channel 212 is a third distance 264C from the focus point 264, the transducer channel 224 is a fourth distance 264D from the focus point 264, the transducer channel 208 is a fifth distance 264E from the focus point 264, the transducer channel 228 is a sixth distance 264F from the focus point 264, the transducer channel 204 is a seventh distance 264G from the focus point 264, and the transducer channel 232 is an eighth distance 264H from the focus point 264.

The transducer channels 216, 220 receive signals that have reflected from the focus point 264 before the transducer channels 204, 208, 212, 224, 228, 232 responsive to the distances 264A, 264B being the shortest distances the reflected signals need to propagate. The transducer channels 204, 232 receive signals that have reflected from the focus point 264 after the transducer channels 208, 212, 216, 220, 224, 228 responsive to the distances 264G, 264H being the greatest distances the reflected signals need to propagate. The beamforming circuitry 190 delays data from the transducer channels 208, 212, 216, 220, 224, 228 by different delay values to account for the variation in the distances 264A, 264B, 264C, 264D, 264E, 264G, 264H. Advantageously, delaying data from the transducer channels 208, 212, 216, 220, 224, 228 by different delay values allows the beamforming circuitry 190 to account for timing differences resulting from the signal propagating across different distances.

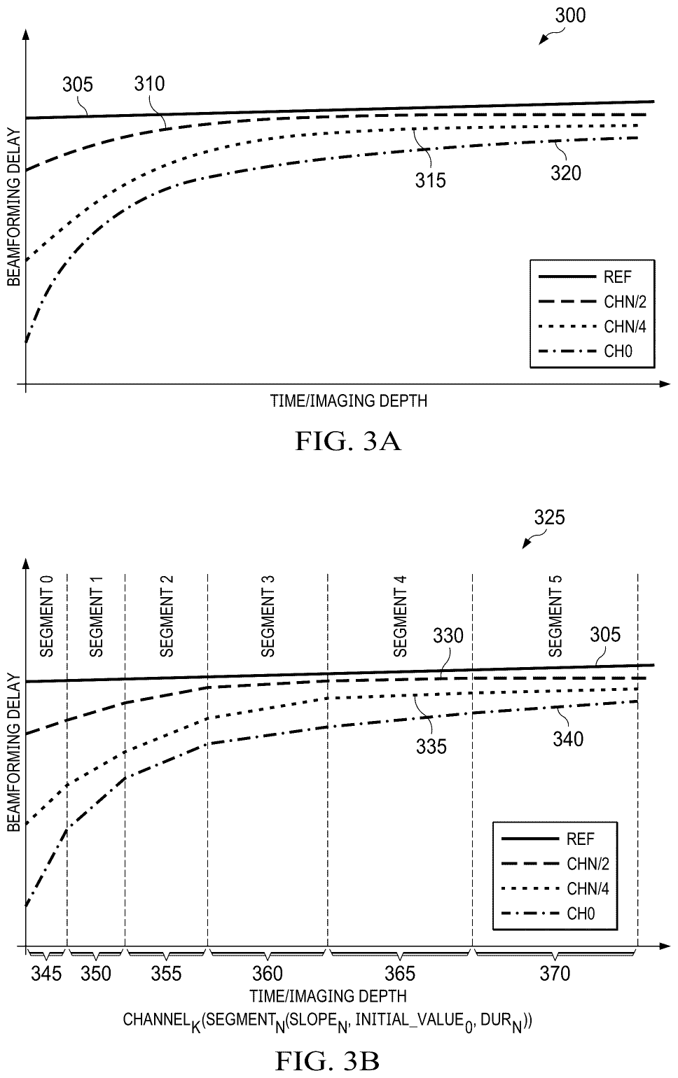

In some such example beamforming operations, distances between the transducer channels 208, 212, 216, 220, 224, 228 and the focus points 260, 264, 268, 272 change across a given beamline. In the example of FIG. 2, the transducer channel 216 is a first distance 268A from the focus point 268, the transducer channel 220 is a second distance 268B from the focus point 268, the transducer channel 212 is a third distance 268C from the focus point 268, the transducer channel 224 is a fourth distance 268D from the focus point 268, the transducer channel 208 is a fifth distance 268E from the focus point 268, the transducer channel 228 is a sixth distance 268F from the focus point 268, the transducer channel 204 is a seventh distance 268G from the focus point 268, and the transducer channel 232 is an eighth distance 268H from the focus point 268. In such examples, the distances 264A, 264B, 264C, 264D, 264E, 264G, 264H are different from the distances 268A, 268B, 268C, 268D, 268E, 268G, 268H responsive to the focus points 264, 268 having different image depths. The beamforming circuitry 190 uses different delay values for data from the transducer channels 208, 212, 216, 220, 224, 228 when processing the focus point 264 than when processing the focus point 268 responsive to the change in image depth. In some examples, as illustrated and further described in FIGS. 3A and 3B, the beamforming circuitry 190 implements an individual delay profile for the transducer channels 208, 212, 216, 220, 224, 228 and the beamlines 244, 248, 252, 256 to determine channels delay value for a focus point.

FIG. 3A is a plot 300 of delay values over an image depth of the image 236 of FIG. 2 for the beamline 252 of FIG. 2. In the example of FIG. 3A, the plot 300 illustrates an example reference delay profile 305, a first example delay profile 310, a second example delay profile 315, and a third example delay profile 320. The plot 300 illustrates the delay profiles 305, 310, 315, 320 formed by delay values of the transducer channels 208, 212, 216, 220, 224, 228 as a focus point moves towards the maximum image depth 240 of FIG. 2 along the beamline 252 (also referred to as a reference beamline). In the example of FIG. 3A, the delay profiles 305, 310, 315, 320 correspond to focus points on the beamline 252. In other examples, alternative delay profiles are used for the transducer channels 208, 212, 216, 220, 224, 228.

The reference delay profile 305 represents delay values of the one of the transducer channels 208, 212, 216, 220, 224, 228 closest to the reference beamline. For example, when the beamline 252 is the reference beamline, the reference delay profile 305 represents the delay values of one of the transducer channels 216, 220. In example operations, the delay values of the reference delay profile 305 are the greatest delay values across the delay profiles 310, 315, 320 responsive to the one of the transducer channels 208, 212, 216, 220, 224, 228 having the shortest propagation distances of the remaining ones of the transducer channels 208, 212, 216, 220, 224, 228. For example, the beamforming circuitry 190 uses the largest delay values for the transducer channels 216, 220 when the beamline being processed is the beamline 252. In another example, the beamforming circuitry 190 uses the largest delay values for the transducer channel 204 when the beamline being processed is the beamline 244. In both examples, the delay values of the transducer channels 208, 212, 216, 220, 224, 228 increase as the distance between the transducer channels 208, 212, 216, 220, 224, 228 and the focus point increases. Also, as the image depth of the focus point increases, the differences in the distances between the focus points and the transducer channels 208, 212, 216, 220, 224, 228 decrease. For focus points having a relatively large image depth (e.g., close to the maximum image depth 240) the delay values of the delay profiles 310, 315, 320 converge at a delay value approximately equal to the delay value of the reference delay profile 305.

The delay profile 310 represents delay values of one of the transducer channels 208, 212, 216, 220, 224, 228 across the depth of the image 236 for the beamline 252. In the example of FIG. 3A, the delay profile 310 corresponds to delay values of one of the transducer channels 208, 212, 216, 220, 224, 228 positioned between the transducer channel of the reference delay profile 305 and the transducer channel corresponding to the delay profile 315. For example, the delay profile 310 corresponds to the transducer channel 212 when the reference delay profile 305 corresponds to the transducer channel 216, and the delay profile 315 corresponds to the transducer channel 208.

The delay profile 315 represents delay values of one of the transducer channels 208, 212, 216, 220, 224, 228 across the depth of the image 236 for the beamline 252. In the example of FIG. 3A, the delay profile 315 corresponds to delay values of one of the transducer channels 208, 212, 216, 220, 224, 228 positioned between the transducer channel corresponding to the delay profile 310 and the channel corresponding to the delay profile 320. For example, the delay profile 315 corresponds to the transducer channel 208 when the delay profile 310 corresponds to the transducer channel 212, and the delay profile 320 corresponds to the transducer channel 204.

The delay profile 320 represents delay values of one of the transducer channels 208, 212, 216, 220, 224, 228 across the depth of the image 236 for the beamline 252. In the example of FIG. 3A, the delay profile 320 corresponds to delay values of one of the transducer channels 208, 212, 216, 220, 224, 228 positioned farthest from the transducer channel corresponding to the reference delay profile 305. For example, when the reference delay profile 305 corresponds to the transducer channel 216, the delay profile 320 corresponds to the transducer channel 204.

In the example of FIG. 3A, the plot 300 illustrates the delay profiles 305, 310, 315, 320. In other examples, the plot 300 may include any plurality of delay profiles corresponding to any number of transducer channels for any beamline. For example, when each delay value is eleven bits, the ultrasound system 100 has thirty-two transducer channels, the image 236 has two-hundred beamlines, and each beamline of the image 236 has ten-thousand focus points, the total data needed to represent the delay values is approximately seven-hundred and four megabits. Making such a relatively large amount of data accessible to the beamforming circuitry 190 increases the complexity of the ultrasound system 100.

FIG. 3B is a plot 325 of delay values over an image depth of the image 236 of FIG. 2 for the beamline 252 of FIG. 2. In the example of FIG. 3B, the plot 325 illustrates the example reference delay profile 305 of FIG. 3A, a first example piecewise delay profile 330, a second example piecewise delay profile 335, and a third example piecewise delay profile 340. The plot 325 illustrates the piecewise delay profiles 330, 335, 340 as piecewise linear representations of the delay profiles 310, 315, 320 of FIG. 3A.

In the example of FIG. 3B, the plot 325 represents the delay profiles 310, 315, 320 using a first segment 345 (SEGMENT0), a second segment 350 (SEGMENT1), a third segment 355 (SEGMENT2), a fourth segment 360 (SEGMENT3), a fifth segment 365 (SEGMENT4), and a sixth segment 370 (SEGMENT5). The segments 345, 350, 355, 360, 365, 370 are defined by a segment duration (DURN). A segment duration spans a portion of the image depth. In some examples, the segments 345, 350, 355, 360, 365, 370 have different durations. For example, the segment 345 has a first duration and the segment 345 has a second duration, which is different from the first duration. Advantageously, as the delay values of the delay profiles 310, 315, 320 converge towards the reference delay profile 305, the segment duration can be increased without decreasing the accuracy.

The piecewise delay profiles 330, 335, 340 have an initial delay value (INITIAL_VALUE_{N}), which corresponds to a delay value at a focus point with the smallest image depth (e.g., closest to the transducer channels). The piecewise delay profiles 330, 335, 340 have a slope value (SLOPE_{N}) for different ones of the segments 345, 350, 355, 360, 365, 370, which represents the change in the delay values across the respective one of the segments 345, 350, 355, 360, 365, 370.

Advantageously, the piecewise delay profiles 330, 335, 340 represent delay values of the delay profiles 310, 315, 320 using an initial value and a slope value for the segments 345, 350, 355, 360, 365, 370. Advantageously, using the piecewise delay profiles 330, 335, 340 to represent the delay profiles 310, 315, 320 decreases the data that needs to be made accessible to the beamforming circuitry 190. For example, when the slope values are ten bits, the duration of the segments 345, 350, 355, 360, 365, 370 are ten bits, the initial values are eleven bits, the total number of segments is thirty-two, the ultrasound system 100 has thirty-two channels, the image 236 has two-hundred beamlines, and each beamline of the image 236 has ten-thousand focus points, the total data needed to represent the delay values using piecewise delay profiles is approximately two and two-tenths megabits. Advantageously, making data representing the piecewise delay profiles 330, 335, 340 accessible to the beamforming circuitry 190 decreases the complexity of the ultrasound system 100.

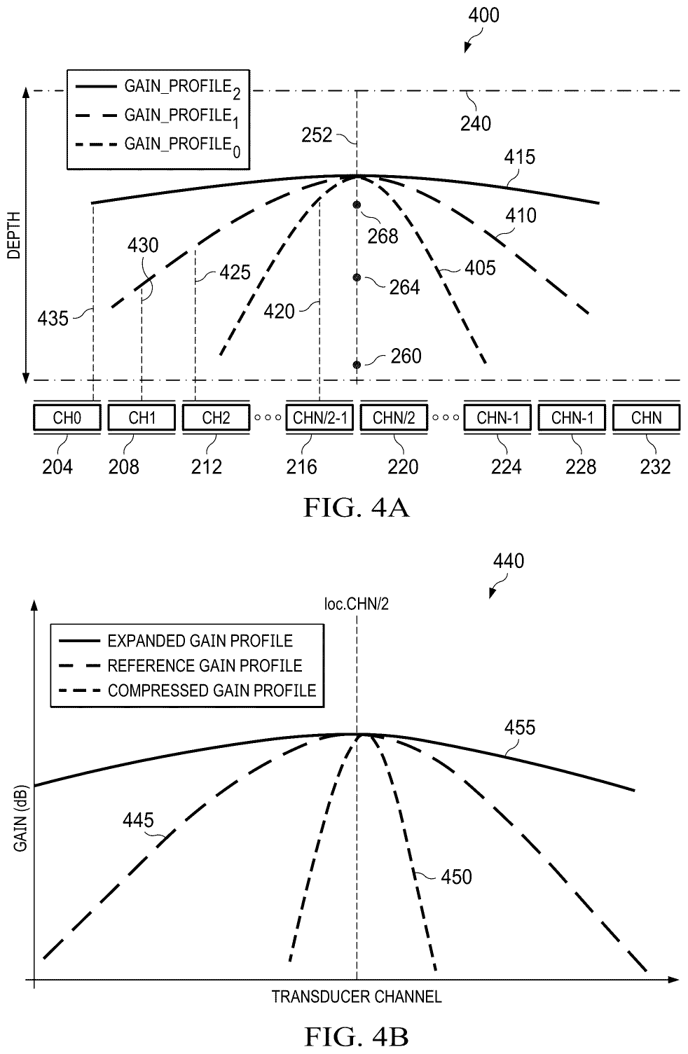

FIG. 4A is a plot 400 of gain values over an image depth of the image 236 of FIG. 2 for the beamline 252 of FIG. 2. In the example of FIG. 4A, the plot 400 includes a first example gain profile 405, a second example gain profile 410, and a third example gain profile 415. In some examples, gain values of the gain profiles 405, 410, 415 are illustrated or described as part of an apodization process or of an apodization profile. Apodization is process of amplifying data from the transducer channels 204, 208, 212, 216, 220, 224, 228, 232 to account for spatial awareness (e.g., angle of incident of the reflected signal) of the focus points in relation to the transducer channels 204, 208, 212, 216, 220, 224, 228, 232. For example, reflected signals from the transducer channels 216, 220 have relatively low noise contributions for the focus point 260. However, the reflected signals from the transducer channels 204, 232 have relatively high noise contributions for the focus point 260. Apodization adjusts gain values to account for the relative noise contributions for a focus point at a certain image depth. As the image depth of the focus point increases, the angle of incident of reflected signals to farther channels increases. In such examples, the gain of the transducer channels 204, 208, 212, 216, 220, 224, 228, 232 begin to converge as the noise contributions from propagating through longer distances begin to converge.

In example apodization operations, the gain profiles 405, 410, 415 represent gain values for the transducer channels 204, 208, 212, 216, 220, 224, 228, 232 at different image depths. The gain profile 405 corresponds to focus points having image depths approximately equal to the image depth of the focus point 260. For example, the transducer channel 216 has an example gain 420 for the focus point 260. The gain profile 410 corresponds to focus points having image depths approximately equal to the image depth of the focus point 264. For example, the transducer channel 212 has a first gain 425 and the transducer channel 208 has a second gain 430 for the focus point 264. The gain profile 415 corresponds to focus points having image depths approximately equal to the image depth of the focus point 268. For example, the transducer channel 435 has an example gain 435 for the focus point 268.

FIG. 4B is a plot 440 of gain values across a channel location of the image 236 of FIG. 2. In the example of FIG. 4B, the plot 440 includes an example reference apodization profile 445, an example compressed gain profile 450, and an example expanded gain profile 455. The reference apodization profile 445 corresponds to focus points having image depths equal to a selected reference image depth. For example, the reference apodization profile 445 has gain values equal to the gain profile 410 of FIG. 4A responsive to the focus point 268 being at the selected reference image depth.

In example apodization operations, expanding and compressing a curvature of the reference apodization profile 445 allows the gain values of the reference apodization profile 445 to represent different image depths. In such example operations, an expansion factor based on an image depth of a selected focus point can expand or compress the reference apodization profile 445 to account for image depths different from the reference image depth. For example, a first expansion factor adjusts the gain values of the reference apodization profile 445 to create the compressed gain profile 450 for a focus point having an image depth less than the reference image depth. In such examples, the compressed gain profile 450 corresponds to the image depth of the focus point 260 of FIG. 2 when the reference image depth is of the focus point 264. In another example, a second expansion factor adjusts the gain values of the reference apodization profile 445 to create the expanded gain profile 455 for a focus point having an image depth greater than the reference image depth. In such examples, the expanded gain profile 455 corresponds to the image depth of the focus point 268 of FIG. 2 when the reference image depth is of the focus point 264. Advantageously, adjusting the reference apodization profile 445 using an expansion factor that accounts for the image depth of a focus point reduces a number of gain profiles needed to implement apodization operations.

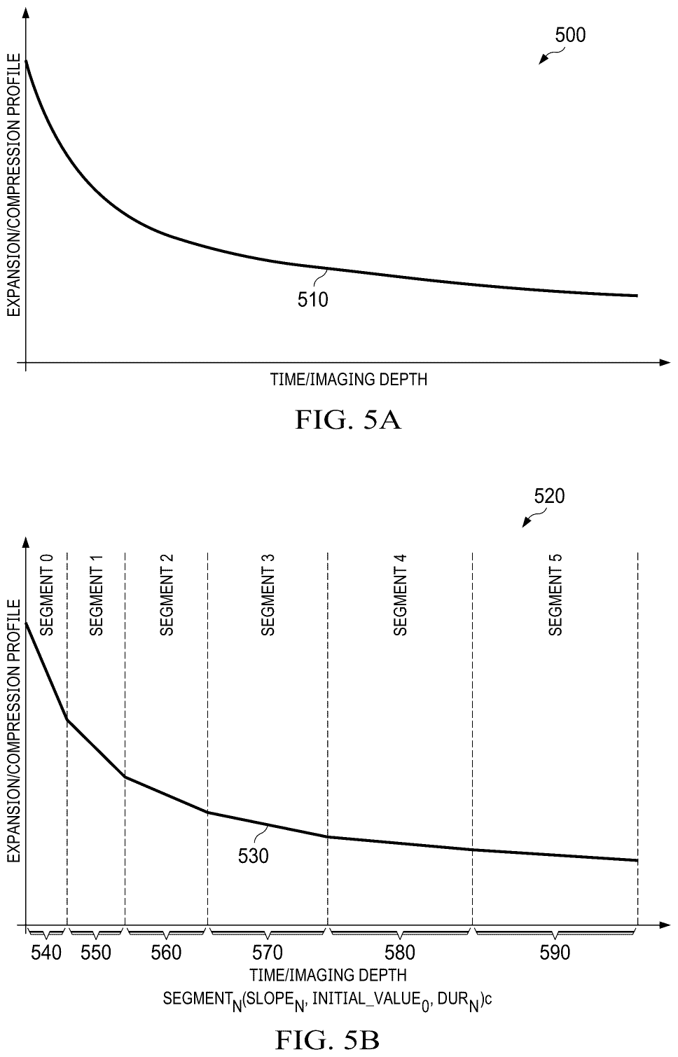

FIG. 5A is a plot 500 of expansion factors over an image depth of the image 236 of FIG. 2. In the example of FIG. 5A, the plot 500 illustrates an example expansion profile 510. The expansion profile 510 illustrates values of an expansion factor to expand and compress a reference apodization profile (e.g., the reference apodization profile 445 of FIG. 4B). In the example of FIG. 5A, the expansion profile 510 has an inverse relationship to image depth. In other examples, the expansion profile 510 may have a different relationship to image depth based on the process of expanding or compressing the reference apodization profile. Advantageously, the expansion factor of the expansion profile 510 accounts for image depth of a focus point.

FIG. 5B is a plot 520 of gain values over an image depth of the image 236 of FIG. 2. In the example of FIG. 5B, the plot 520 illustrates an example piecewise expansion profile 530. The plot 520 illustrates the piecewise expansion profile 530 as piecewise linear representations of the expansion profile 510 of FIG. 5A. In the example of FIG. 5B, the plot 520 represents the expansion profile 510 using a first segment 540 (SEGMENT0), a second segment 550 (SEGMENT1), a third segment 560 (SEGMENT2), a fourth segment 570 (SEGMENT3), a fifth segment 580 (SEGMENT4), and a sixth segment 590 (SEGMENT5). The segments 540, 550, 560, 570, 580, 590 are defined by a segment duration (DUR). A segment duration spans a portion of the image depth. In some examples, the segments 540, 550, 560, 570, 580, 590 have different durations. For example, the segment 540 has a first duration and the segment 550 has a second duration, which is different than the first duration. Advantageously, as the delay values of the expansion profile 510 converges towards a steady state, the duration of the segments can be increased without decreasing the accuracy.

The piecewise expansion profile 530 has an initial expansion factor value, which corresponds to an expansion factor at a focus point with the smallest image depth. The piecewise expansion profile 530 has a slope value for different ones of the segments 540, 550, 560, 570, 580, 590, which represents the change in the expansion factor across the respective one of the segments 540, 550, 560, 570, 580, 590. Advantageously, the piecewise expansion profile 530 represents an expansion or compression of the reference apodization profile 445 of FIG. 4B using an initial value and a slope value for the segments 540, 550, 560, 570, 580, 590. Advantageously, using the piecewise expansion profile 530 to represent the expansion profile 510 decreases the data that needs to be made accessible to the beamforming circuitry 190. Advantageously, making data representing the piecewise expansion profile 530 accessible to the beamforming circuitry 190 decreases the complexity of the ultrasound system 100.

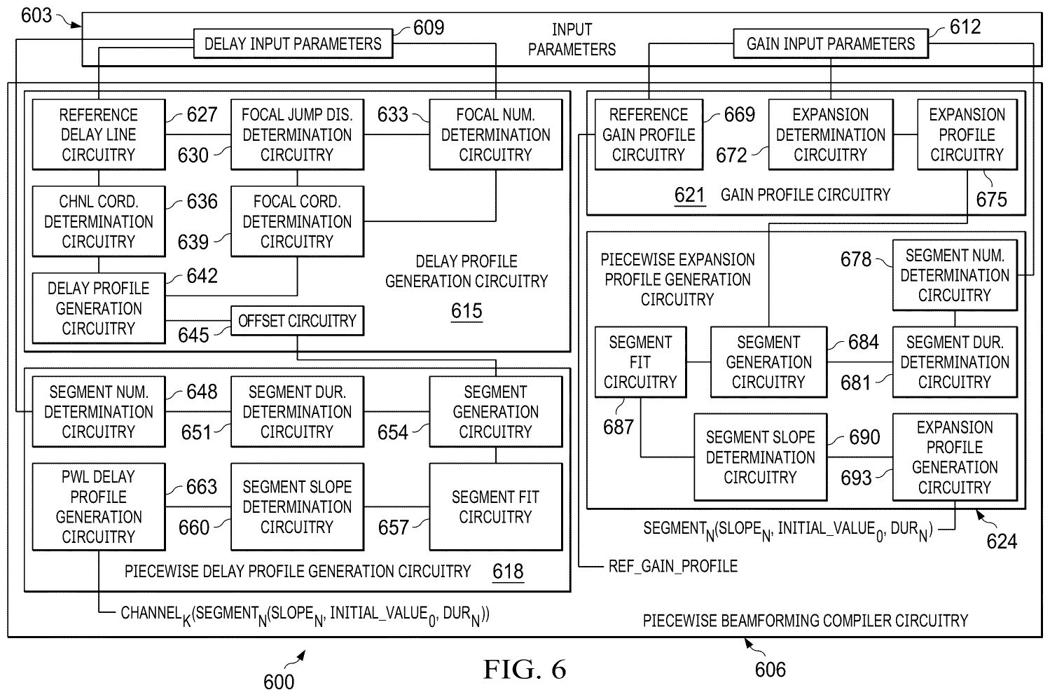

FIG. 6 is a block diagram of an example piecewise beamforming generation system 600. In the example of FIG. 6, the piecewise beamforming generation system 600 includes input parameters 603 and piecewise beamforming compiler circuitry 606. The example input parameters 603 of FIG. 6 includes example delay input parameters 609 and example gain input parameters 612. The example piecewise beamforming compiler circuitry 606 of FIG. 6 includes example delay profile generation circuitry 615, example piecewise delay profile generation circuitry 618, example gain profile circuitry 621, and example piecewise expansion profile generation circuitry 624. The piecewise beamforming compiler circuitry 606 of FIG. 6 may be instantiated (e.g., creating an instance of, bring into being for any length of time, materialize, implement, etc.) by programmable circuitry such as a Central Processor Unit (CPU) executing first instructions. Also or alternatively, the piecewise beamforming compiler circuitry 606 of FIG. 6 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 6 may, thus, be instantiated at the same or different times. Some or all of the circuitry of FIG. 6 may be instantiated, for example, in one or more threads executing concurrently on hardware or in series on hardware. Moreover, in some examples, some or all of the circuitry of FIG. 6 may be implemented by microprocessor circuitry executing instructions or FPGA circuitry performing operations to implement one or more virtual machines or containers.

The example delay profile generation circuitry 615 of FIG. 6 includes example reference delay line circuitry 627, example focal jump distance determination circuitry 630, example focal number determination circuitry 633, example channel coordinate determination circuitry 636, example focal coordinate determination circuitry 639, example delay profile generation circuitry 642, and example offset circuitry 645. The example piecewise delay profile generation circuitry 618 of FIG. 6 includes example segment number determination circuitry 648, example segment duration determination circuitry 651, example segment generation circuitry 654, example segment fit circuitry 657, example segment slope determination circuitry 660, example piecewise linear (PWL) delay profile generation circuitry 663. The example gain profile circuitry 621 of FIG. 6 includes example reference gain profile circuitry 669, example expansion determination circuitry 672, and example expansion profile circuitry 675. The example piecewise expansion profile generation circuitry 624 of FIG. 6 includes example segment number determination circuitry 678, example segment duration determination circuitry 681, example segment generation circuitry 684, example segment fit circuitry 687, example segment slope determination circuitry 690, and example expansion profile generation circuitry 693.

The input parameters 603 are coupled to the piecewise beamforming compiler circuitry 606. In some examples, the input parameters 603 are user defined inputs, which specify characteristics of delay values and gain values for beamforming operations. Also, the input parameters 603 may include data that specifies desired output characteristics of data of piecewise delay profiles or a piecewise expansion profile. For example, the input parameters 603 allow a user to define characteristics of a specific implementation of the ultrasound system 100 of FIG. 1, such as a specific number of or configuration of the transducer channels 140, 150, 160 of FIG. 1.

The piecewise beamforming compiler circuitry 606 is coupled to the input parameters 603. In some examples, the piecewise beamforming compiler circuitry 606 is also coupled to memory circuitry, which stores data from the piecewise beamforming compiler circuitry 606 for beamforming. In such examples, the programmable circuitry 110 of FIG. 1 may be structured to transfer data from the piecewise beamforming compiler circuitry 606 to memory circuitry internal to the beamforming circuitry 190 of FIG. 1 responsive to the ultrasound system 100 being turned on. Such memory circuitry, internal to the AFE circuitry 130 is illustrated and described in connection with FIG. 12, below.

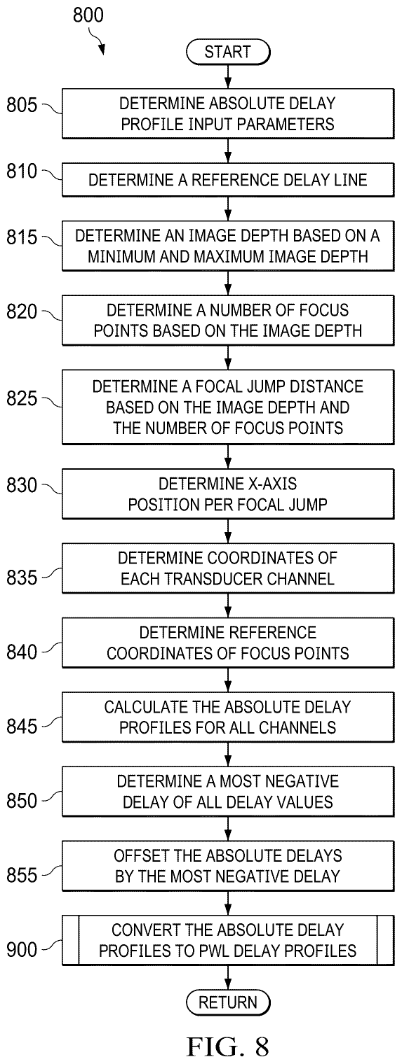

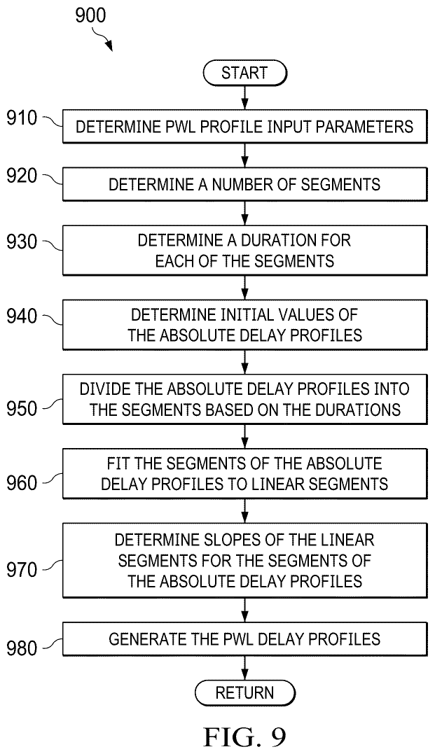

The delay input parameters 609 are coupled to the delay profile generation circuitry 615 and the piecewise delay profile generation circuitry 618. The delay input parameters 609 specify characteristics of a beamforming system, such as positioning information of transducer channels and characteristics of delay profiles. Examples of the delay input parameters 609 are further described below in connection with FIGS. 8 and 9.

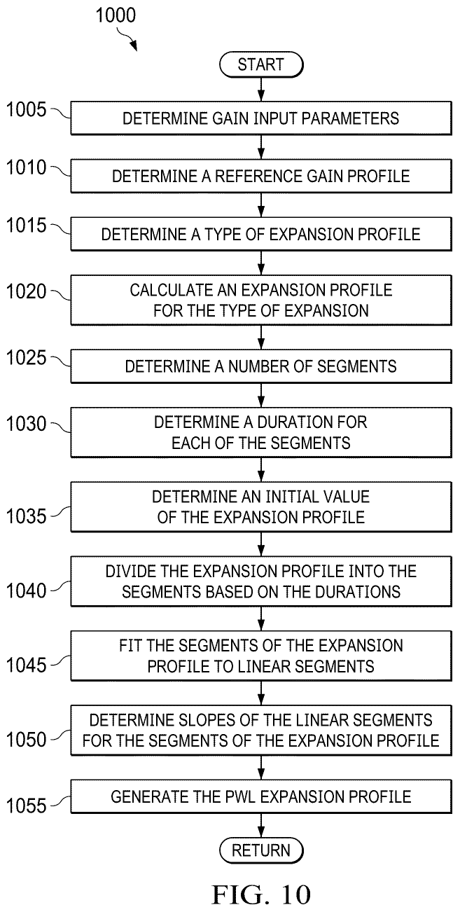

The gain input parameters 612 are coupled to the gain profile circuitry 621 and the piecewise expansion profile generation circuitry 624. The gain input parameters 612 specify characteristics of a reference apodization profile (e.g., the reference apodization profile 445 of FIG. 4B), such as gain values based on a positioning of a transducer channel from a reference position, and characteristics of an expansion or compression of the reference apodization profile. Examples of the gain input parameters 612 are further described below in connection with FIG. 10.

The delay profile generation circuitry 615 is coupled to the input parameters 603 and the piecewise delay profile generation circuitry 618. Example operations of the delay profile generation circuitry 615 are illustrated and described in connection with FIG. 8, below.

The piecewise delay profile generation circuitry 618 is coupled to the input parameters 603 and the delay profile generation circuitry 615. In some examples, the piecewise delay profile generation circuitry 618 is coupled to memory circuitry, which stores data representing piecewise delay profiles for beamforming. Example operations of the piecewise delay profile generation circuitry 618 are illustrated and described in connection with FIG. 9, below.

The gain profile circuitry 621 is coupled to the input parameters 603 and the piecewise expansion profile generation circuitry 624. In some examples, the gain profile circuitry 621 is coupled to memory circuitry, which stores data representing a reference apodization profile for beamforming. Example operations of the gain profile circuitry 621 are illustrated and described in connection with FIG. 10, below.

The piecewise expansion profile generation circuitry 624 is coupled to the input parameters and the gain profile circuitry 621. In some examples, the piecewise expansion profile generation circuitry 624 is coupled to memory circuitry, which stores data representing a piecewise expansion profile for beamforming. Example operations of the piecewise expansion profile generation circuitry 624 are illustrated and described in connection with FIG. 10, below.

The reference delay line circuitry 627 has a first terminal, a second terminal, and a third terminal. The first terminal of the reference delay line circuitry 627 is coupled to the input parameters 603, which supplies the delay input parameters 609. The second terminal of the reference delay line circuitry 627 is coupled to the focal jump distance determination circuitry 630. The third terminal of the reference delay line circuitry 627 is coupled to the channel coordinate determination circuitry 636. In some examples, the reference delay line circuitry 627 is instantiated by programmable circuitry executing reference delay line instructions to perform operations such as those represented by the flowchart of FIG. 8.

The focal jump distance determination circuitry 630 has a first terminal, a second terminal, and a third terminal. The first terminal of the focal jump distance determination circuitry 630 is coupled to the reference delay line circuitry 627. The second terminal of the focal jump distance determination circuitry 630 is coupled to the focal number determination circuitry 633. The third terminal of the focal jump distance determination circuitry 630 is coupled to the focal coordinate determination circuitry 636. In some examples, the focal jump distance determination circuitry 630 is instantiated by programmable circuitry executing focal jump distance determination instructions to perform operations such as those represented by the flowchart of FIG. 8.

The focal number determination circuitry 633 has a first terminal and a second terminal. The first terminal of the focal number determination circuitry 633 is coupled to the input parameters 603, which supplies the delay input parameters 609. The second terminal of the focal number determination circuitry 633 is coupled to the focal jump distance determination circuitry 630. In some examples, the focal number determination circuitry 633 is instantiated by programmable circuitry executing focal number determination instructions to perform operations such as those represented by the flowchart of FIG. 8.

The channel coordinate determination circuitry 636 has a first terminal and a second terminal. The first terminal of the channel coordinate determination circuitry 636 is coupled to the reference delay line circuitry 627. The second terminal of the channel coordinate determination circuitry 636 is coupled to the delay profile generation circuitry 642. In some examples, the channel coordinate determination circuitry 636 is instantiated by programmable circuitry executing channel coordinate determination instructions to perform operations such as those represented by the flowchart of FIG. 8.

The focal coordinate determination circuitry 639 has a first terminal and a second terminal. The first terminal of the focal coordinate determination circuitry 639 is coupled to the focal jump distance determination circuitry 630. The second terminal of the focal coordinate determination circuitry 639 is coupled to the delay profile generation circuitry 642. In some examples, the focal coordinate determination circuitry 639 is instantiated by programmable circuitry executing focal coordinate determination instructions to perform operations such as those represented by the flowchart of FIG. 8.

The delay profile generation circuitry 642 has a first terminal, a second terminal, and a third terminal. The first terminal of the delay profile generation circuitry 642 is coupled to the channel coordinate determination circuitry 636. The second terminal of the delay profile generation circuitry 642 is coupled to the focal coordinate determination circuitry 639. The third terminal of the delay profile generation circuitry 642 is coupled to the offset circuitry 645. In some examples, the delay profile generation circuitry 642 is instantiated by programmable circuitry executing delay profile generation instructions to perform operations such as those represented by the flowchart of FIG. 8.

The offset circuitry 645 has a first terminal and a second terminal. The first terminal of the offset circuitry 645 is coupled to the delay profile generation circuitry 642. The second terminal of the offset circuitry 645 is coupled to the piecewise delay profile generation circuitry 618. In some examples, the offset circuitry 645 is instantiated by programmable circuitry executing offset instructions to perform operations such as those represented by the flowchart of FIG. 8.

The segment number determination circuitry 648 has a first terminal and a second terminal. The first terminal of the segment number determination circuitry 648 is coupled to the input parameters 603, which supplies the delay input parameters 609. The second terminal of the segment number determination circuitry 648 is coupled to the segment duration determination circuitry 651. In some examples, the segment number determination circuitry 648 is instantiated by programmable circuitry executing segment number determination instructions to perform operations such as those represented by the flowchart of FIG. 9.

The segment duration determination circuitry 651 has a first terminal and a second terminal. The first terminal of the segment duration determination circuitry 651 is coupled to the segment number determination circuitry 648. The second terminal of the segment duration determination circuitry 651 is coupled to the segment generation circuitry 654. In some examples, the segment duration determination circuitry 651 is instantiated by programmable circuitry executing segment duration determination instructions to perform operations such as those represented by the flowchart of FIG. 9.

The segment generation circuitry 654 has a first terminal, a second terminal, and a third terminal. The first terminal of the segment generation circuitry 654 is coupled to the delay profile generation circuitry 615, which supplies delay values of delay profiles. The second terminal of the segment generation circuitry 654 is coupled to the segment duration determination circuitry 651. The third terminal of the segment generation circuitry 654 is coupled to the segment fit circuitry 657. In some examples, the segment generation circuitry 654 is instantiated by programmable circuitry executing segment generation instructions to perform operations such as those represented by the flowchart of FIG. 9.

The segment fit circuitry 657 has a first terminal and a second terminal. The first terminal of the segment fit circuitry 657 is coupled to the segment generation circuitry 654. The second terminal of the segment fit circuitry 657 is coupled to the segment slope determination circuitry 660. In some examples, the segment fit circuitry 657 is instantiated by programmable circuitry executing segment fit instructions to perform operations such as those represented by the flowchart of FIG. 9.

The segment slope determination circuitry 660 has a first terminal and a second terminal. The first terminal of the segment slope determination circuitry 660 is coupled to the segment fit circuitry 657. The second terminal of the segment slope determination circuitry 660 is coupled to the PWL delay profile generation circuitry 663. In some examples, the segment slope determination circuitry 660 is instantiated by programmable circuitry executing segment slope determination instructions to perform operations such as those represented by the flowchart of FIG. 9.

The PWL delay profile generation circuitry 663 has a first terminal and a second terminal. The first terminal of the PWL delay profile generation circuitry 663 is coupled to the segment slope determination circuitry 660. The second terminal of the PWL delay profile generation circuitry 663 may be coupled to memory circuitry that is structured to store data of piecewise delay profiles for beamforming. In some examples, the PWL delay profile generation circuitry 663 is instantiated by programmable circuitry executing PWL delay profile generation instructions to perform operations such as those represented by the flowchart of FIG. 9.

The reference gain profile circuitry 669 has a first terminal and a second terminal. The first terminal of the reference gain profile circuitry 669 is coupled to the input parameters 603, which supplies the gain input parameters 612. The second terminal of the reference gain profile circuitry 669 may be coupled to memory circuitry, which is structured to store data of piecewise delay profiles for beamforming. In some examples, the reference gain profile circuitry 669 is instantiated by programmable circuitry executing reference gain profile instructions to perform operations such as those represented by the flowchart of FIG. 10.

The expansion determination circuitry 672 has a first terminal and a second terminal. The first terminal of the expansion determination circuitry 672 is coupled to the input parameters 603, which supplies the gain input parameters 612. The second terminal of the expansion determination circuitry 672 is coupled to the expansion profile circuitry 675. In some examples, the expansion determination circuitry 672 is instantiated by programmable circuitry executing expansion determination instructions to perform operations such as those represented by the flowchart of FIG. 10.

The expansion profile circuitry 675 has a first terminal and a second terminal. The first terminal of the expansion profile circuitry 675 is coupled to the expansion determination circuitry 672. The second terminal of the expansion profile circuitry 675 is coupled to the piecewise expansion profile generation circuitry 624. In some examples, the expansion profile circuitry 675 is instantiated by programmable circuitry executing expansion profile instructions to perform operations such as those represented by the flowchart of FIG. 10.

The segment number determination circuitry 678 has a first terminal and a second terminal. The first terminal of the segment number determination circuitry 678 is coupled to the input parameters 603, which supplies the gain input parameters 612. The second terminal of the segment number determination circuitry 678 is coupled to the segment duration determination circuitry 681. In some examples, the segment number determination circuitry 678 is instantiated by programmable circuitry executing segment number determination instructions to perform operations such as those represented by the flowchart of FIG. 10.

The segment duration circuitry 681 has a first terminal and a second terminal. The first terminal of the segment duration determination circuitry 681 is coupled to the segment number determination circuitry 678. The second terminal of the segment duration determination circuitry 681 is coupled to the segment generation circuitry 684. In some examples, the segment duration determination circuitry 681 is instantiated by programmable circuitry executing segment duration instructions to perform operations such as those represented by the flowchart of FIG. 10.

The segment generation circuitry 684 has a first terminal, a second terminal, and a third terminal. The first terminal of the segment generation circuitry 684 is coupled to the gain profile circuitry 621. The second terminal of the segment generation circuitry 684 is coupled to the segment duration determination circuitry 681. The third terminal of the segment generation circuitry 684 is coupled to the segment fit circuitry 687. In some examples, the segment generation circuitry 684 is instantiated by programmable circuitry executing segment generation instructions to perform operations such as those represented by the flowchart of FIG. 10.

The segment fit circuitry 687 has a first terminal and a second terminal. The first terminal of the segment fit circuitry 687 is coupled to the segment generation circuitry 684. The second terminal of the segment fit circuitry 687 is coupled to the segment slope determination circuitry 690. In some examples, the segment fit circuitry 687 is instantiated by programmable circuitry executing segment fit instructions to perform operations such as those represented by the flowchart of FIG. 10.

The segment slope determination circuitry 690 has a first terminal and a second terminal. The first terminal of the segment slope determination circuitry 690 is coupled to the segment fit circuitry 687. The second terminal of the segment slope determination circuitry 690 is coupled to the expansion profile generation circuitry 693. In some examples, the segment slope determination circuitry 690 is instantiated by programmable circuitry executing segment slope determination instructions to perform operations such as those represented by the flowchart of FIG. 10.

The expansion profile generation circuitry 693 has a first terminal and a second terminal. The first terminal of the expansion profile generation circuitry 693 is coupled to the segment slope determination circuitry 690. The second terminal of the expansion profile generation circuitry 693 may be coupled to memory circuitry, which is structured to store data of a piecewise expansion profile for beamforming. In some examples, the expansion profile generation circuitry 693 is instantiated by programmable circuitry executing expansion profile generation instructions to perform operations such as those represented by the flowchart of FIG. 10.

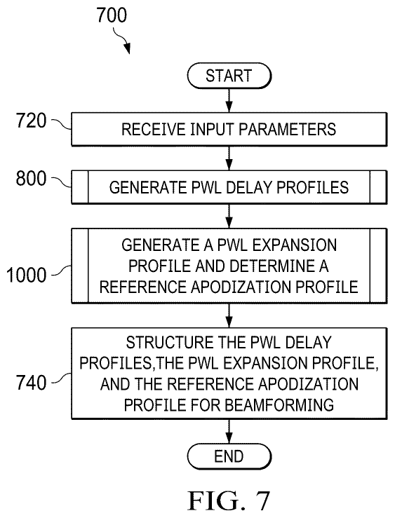

FIG. 7 is a flowchart representative of example machine-readable instructions or example operations 700 that may be at least one of executed, instantiated, or performed using an example programmable circuitry implementation of the piecewise beamforming compiler circuitry 606 of FIG. 6. The example operations 700 of FIG. 7 begin at Block 720 at which the piecewise beamforming compiler circuitry 606 receives input parameters. (Block 720). In some examples, the piecewise beamforming compiler circuitry 606 receives the delay input parameters 609 of FIG. 6 and the gain input parameters 612 of FIG. 6 as the input parameters 603 of FIG. 6. In some such examples, the input parameters 603 are supplied by a user.

The delay profile generation circuitry 615 of FIG. 6 and the piecewise delay profile generation circuitry 618 of FIG. 6 generate PWL delay profiles. (Operations 800 of FIG. 8, below). In some examples, the delay profile generation circuitry 615 determines delay values to generate the delay profiles 310, 315, 320 of FIG. 3A. In such examples, the piecewise delay profile generation circuitry 618 converts the delay values of the delay profiles 310, 315, 320 to the piecewise delay profiles 330, 335, 340 of FIG. 3B. In example operations, the delay profile generation circuitry 615 generates delay values to generate delay profiles for the transducer channels 204, 208, 212, 216, 220, 224, 228, 232 and the beamlines 244, 248, 252, 256.

The gain profile circuitry 621 of FIG. 6 and the piecewise expansion profile generation circuitry 624 of FIG. 6 generates a PWL expansion profile and determines a reference apodization profile. (Operations 1000 of FIG. 10, below). In some examples, the gain profile circuitry 621 determines gain values of the reference apodization profile 445 of FIG. 4B and expansion factor values of the expansion profile 510 of FIG. 5A. In such examples, the piecewise expansion profile generation circuitry 624 converts the expansion factor values of the expansion profile 510 to the piecewise expansion profile 530 of FIG. 5B. In example operations, the gain values of the reference apodization profile 445 are the same across the beamlines 244, 248, 252, 256. In such example operations, the peak of the reference apodization profile 445 shifts based on a location of the beamline being processed.

The piecewise delay profile generation circuitry 618 and the piecewise expansion profile generation circuitry 624 structure the PWL delay profiles, the PWL expansion profile, and the reference apodization profile for beamforming. (Block 740). In some examples, the piecewise delay profile generation circuitry 618 and the piecewise expansion profile generation circuitry 624 store data of the PWL delay profiles, the PWL expansion profile, and the reference apodization profile to memory circuitry. In such examples, the memory circuitry is structured to supply the PWL delay profiles, the PWL expansion profile, and the reference apodization profile to the beamforming circuitry 190 of FIG. 1. Control proceeds to end.

Example methods are described with reference to the flowchart illustrated in FIG. 7. However, many other methods of implementing the piecewise beamforming compiler circuitry 606 of FIG. 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 8 is a flowchart representative of example machine-readable instructions or example operations 800 that may be at least one of executed, instantiated, or performed using an example programmable circuitry implementation of the piecewise beamforming compiler circuitry 606 of FIG. 6 to generate the delay profiles 305, 310, 315, 320 of FIG. 3A. The example operations 800 of FIG. 8 begin at Block 805, at which the delay profile generation circuitry 615 of FIG. 6 determines absolute delay profile input parameters. (Block 805). In some examples, the delay profile generation circuitry 615 receives the delay input parameters 609 of FIG. 6 of the input parameters 603 of FIG. 6.

The reference delay line circuitry 627 of FIG. 6 determines reference delay lines. (Block 810). In some examples, the reference delay line circuitry 627 determines the reference delay profile to be delay values of a channel that is closest to each beamline. For example, the reference delay line circuitry 627 determines that the reference delay profile 305 of FIG. 3A is the reference delay line for the transducer channel 216 of FIG. 2 responsive to determining the beamline 252 of FIG. 2 is closest to the transducer channel 216. In such examples, the delay values of the delay profiles 310, 315, 320 of FIG. 3A are determined in relation to the reference delay profile 305.

The focal number determination circuitry 633 of FIG. 6 determines an image depth based on a minimum and maximum image depth. (Block 815). In some examples, the focal number determination circuitry 633 determines the minimum distance between the transducer channels 204, 208, 212, 216, 220, 224, 228, 232 and a focus point on a beamline as the minimum image depth. In such examples, the focal number determination circuitry 633 determines a maximum distance along a beamline between the transducer channels 204, 208, 212, 216, 220, 224, 228, 232 and a focus point as a maximum image depth (e.g., the maximum image depth 240 of FIG. 2). The focal number determination circuitry 633 determines the image depth of the image 236 of FIG. 2 to be the distances between the minimum and maximum image depths.

The focal number determination circuitry 633 determines a number of focus points based on the image depth. (Block 820). In some examples, the focal number determination circuitry 633 determines a minimum number of focus points across one of the beamlines 244, 248, 252, 256 of FIG. 2. In such examples, the focal number determination circuitry 633 determines the number of focus points along the image depth based on a desired resolution of the image 236.

The focal jump distance determination circuitry 630 determines a focal jump distance. (Block 825). In some examples, the focal jump distance determination circuitry 630 determines a change in image depth per focus point as a focal jump distance. In such examples, the focal jump distance is the image depth divided by the number of focus points along the image depth.

The focal jump distance determination circuitry 630 determines x-axis position per focal jump. (Block 830). In some examples, the transducer channels 204, 208, 212, 216, 220, 224, 228, 232 are radially positioned. In such examples, the change in distance along the x-axis per focal jump is determined based on the radius of curvature of the transducer channels 204, 208, 212, 216, 220, 224, 228, 232.

The channel coordinate determination circuitry 636 of FIG. 6 determines coordinates of each transducer channel. (Block 835). In some examples, the channel coordinate determination circuitry 636 determines the coordinates of the transducer channels 204, 208, 212, 216, 220, 224, 228, 232 in relation to a reference location, which defines an origin. For example, when the transducer channel 216 is determined to be the reference location, the transducer channels 204, 208, 212 have negative x-axis coordinates and the transducer channels 220, 224, 228, 232 have positive x-axis coordinates.

The focal coordinate determination circuitry 639 of FIG. 6 determines reference coordinates for focus points of an image. (Block 840). In some examples, the focal coordinate determination circuitry 639 generates coordinates for the focus points across the beamlines 244, 248, 252, 256 in relation to the reference location. For example, the focal coordinate determination circuitry 639 generates coordinates for the focus points along the beamlines 244, 248, 252, 256.

The delay profile generation circuitry 642 of FIG. 6 calculates the absolute delay profiles for all channels. (Block 845). In some examples, the delay profile generation circuitry 642 calculates a distance between the focus points and the location of the transducer channels 204, 208, 212, 216, 220, 224, 228, 232. For example, the delay profile generation circuitry 642 determines the distances 264A, 264B, 264C, 264D, 264E, 264F, 264G, 264H for the focus point 264 and the transducer channels 204, 208, 212, 216, 220, 224, 228, 232. In such examples, the delay profile generation circuitry 642 determines a first delay value for the distances 264A, 264B, a second delay value for the distances 264C, 264D, a third delay value for the distances 264E, 264F, and a fourth delay value for the distances 264G, 264H. The first delay value is greater than the second delay value responsive to the distances 264A, 264B being less than the distances 264C, 264D. In such examples, the difference between the delay values accounts for the difference in time it takes for the transducer channels 204, 208, 212, 216, 220, 224, 228, 232 to receive the reflected signal after propagating to the focus point 264. In example operations, the delay profile generation circuitry 642 decreases the delay value as the distance between the corresponding one of the transducer channels 204, 208, 212, 216, 220, 224, 228, 232 and the focus points increase.

The offset circuitry 645 of FIG. 6 determines a most negative delay of all delay values. (Block 850). In some examples, the offset circuitry 645 determines the largest negative delay value, which corresponds to the largest distance between one of the transducer channels 204, 208, 212, 216, 220, 224, 228, 232 and a focus point.

The offset circuitry 645 offsets the absolute delays by the most negative delay. (Block 855). In some examples, the offset circuitry 645 subtracts the most negative delay value from the determined delay values. In such examples, the offset circuitry 645 shifts the determined delay values to only have positive delay values.

The piecewise delay profile generation circuitry 618 converts the absolute delay profiles to PWL delay profiles. (Operations 900 of FIG. 9, below). In some examples, the piecewise delay profile generation circuitry 618 generates the piecewise delay profiles 330, 335, 340 responsive to the delay profile generation circuitry 615 supplying the delay values of the delay profiles 310, 315, 320.

Example methods are described with reference to the flowchart illustrated in FIG. 8. However, many other methods of implementing the piecewise beamforming compiler circuitry 606 of FIG. 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 9 is a flowchart representative of example machine-readable instructions or example operations 900 that may be at least one of executed, instantiated, or performed using an example programmable circuitry implementation of the piecewise beamforming compiler circuitry 606 of FIG. 6 to generate the piecewise delay profiles 330, 335, 340 of FIG. 3B.

The example operations 900 begin at Block 910, at which the piecewise delay profile generation circuitry 618 of FIG. 6 determines PWL profile input parameters. (Block 910). In some examples, the piecewise delay profile generation circuitry 618 receives delay values of the delay profiles 310, 315, 320 from the delay profile generation circuitry 615 and parameters of the piecewise delay profiles 330, 335, 340 from the delay input parameters 609. In such examples, the parameters of the piecewise delay profiles 330, 335, 340 may include one or more of a maximum segment duration size, a maximum slope size, a fine delay resolution, a maximum segment number, a slope resolution, a beamforming clock frequency, an acceptable error value, a memory size values, a start memory address, etc.

The maximum segment duration size represents a maximum number of bits the piecewise delay profile generation circuitry 618 may use to represent the segment duration. The maximum slope size represents a maximum number of bits the piecewise delay profile generation circuitry 618 may use to represent a slope of a segment. The fine delay resolution specifies a number of bits of the delay value corresponding to a fine delay duration. The maximum segment number specifies a maximum number of segments the piecewise delay profile generation circuitry 618 may use to generate a piecewise delay profile.

The slope resolution represents a number of bits that represent a slope of a segment of the piecewise delay profiles 330, 335, 340. The beamforming clock frequency defines a time in which beamforming occurs for a focus point. Also, the beamforming clock frequency represents the rate at which focus points are processed. The acceptable error value defines a tolerance of a matching of the delay value of the delay profiles 310, 315, 320 to segments of the piecewise delay profiles 330, 335, 340. The memory size values identify a memory profile to use when structuring data for beamforming. The start memory address specifies a start memory address to begin storing data of the piecewise delay profiles 330, 335, 340.

The segment number determination circuitry 648 of FIG. 6 determines a number of segments. (Block 920). In some examples, the segment number determination circuitry 648 determines a number of segments of a piecewise delay profile. In such examples, the segment number determination circuitry 648 sets the number of segments to a range of possible values based on the maximum segment number from the delay input parameters 609. In other examples, the delay input parameters 609 specify a specific number of delay segments. In such examples, the segment number determination circuitry 648 sets the number of segments to a fixed number.

The segment duration determination circuitry 651 of FIG. 6 determines a duration for each of the segments. (Block 930). In some examples, the segment duration determination circuitry 651 divides the image depth by the number of segments. In some such examples, the segment duration determination circuitry 651 dynamically divides the image depth across the number of segments. For example, the segment duration determination circuitry 651 increases the segment durations as the image depth increases, such as in the segments 345, 350, 355, 360, 365, 370 of FIG. 3B. In such examples, the segment duration increases as the image depth approaches the maximum image depth 240 of FIG. 2 and the delay values begin to converge to a steady state value.

The segment generation circuitry 654 of FIG. 6 determines initial values of the absolute delay profiles. (Block 940). In some examples, the segment generation circuitry 654 receives the delay values of the delay profiles 310, 315, 320 from the delay profile generation circuitry 615. In such examples, the segment generation circuitry 654 determines initial values of the delay profiles to be a delay value at a minimum image depth. In other examples, the segment generation circuitry 654 determines the initial value of segments based on the determined number of segments and the determined segment durations.

The segment generation circuitry 654 divides the absolute delay profiles into the segments based on the durations. (Block 950). In some examples, the segment generation circuitry 654 splits the delay values of the delay profiles 310, 315, 320 into individual segments based on the segment durations. For example, the segment generation circuitry 654 allocates a first plurality of delay values to a first segment responsive to the first plurality of delay values spanning a first duration. In such examples, the first segment has an initial value and a duration.

The segment fit circuitry 657 of FIG. 6 fits the segments of the absolute delay profiles to linear segments. (Block 960). In some examples, the segment fit circuitry 657 fits the delay values of the segments to linear segments. In some such examples, the segment fit circuitry 657 generates a linear approximation of the delay values of the segments. In example operation, when the segment fit circuitry 657 is unable to fit the delay values to a linear segment or achieve an acceptable error value, from the delay input parameters 609, the piecewise delay profile generation circuitry 618 may return to one of Blocks 920, 930 to determine an alternative number of segments or alternative segment durations of the previous number of segments.

The segment slope determination circuitry 660 of FIG. 6 determines a slope of the linear plot of the segments of the absolute delay profiles. (Block 970). In some examples, the segment slope determination circuitry 660 determines a slope of the linear segments determined by the segment fit circuitry 657.

The PWL delay profile generation circuitry 663 of FIG. 6 generates the PWL delay profiles. (Block 980). In some examples, the PWL delay profile generation circuitry 663 forms data structures representing the piecewise delay profiles 330, 335, 340. For example, the PWL delay profile generation circuitry 663 structures the segment duration of the segments 345, 350, 355, 360, 365, 370 for all of the piecewise delay profiles 330, 335, 340, the initial values of the piecewise delay profiles 330, 335, 340, and the slope values of the segments of the piecewise delay profiles 330, 335, 340. Also, the PWL delay profile generation circuitry 663 may use the memory profile and start address in memory to write data of the piecewise delay profiles 330, 335, 340 to memory for beamforming. Control proceeds to return.

Example methods are described with reference to the flowchart illustrated in FIG. 9. However, many other methods of implementing the piecewise beamforming compiler circuitry 606 of FIG. 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 10 is a flowchart representative of example machine-readable instructions or example operations that may be at least one of executed, instantiated, or performed using an example programmable circuitry implementation of the piecewise beamforming compiler circuitry 606 of FIG. 6 to generate the piecewise expansion profile 530 of FIG. 5B.

The example operations 1000 of FIG. 10 begin at Block 1005, at which the gain profile circuitry 621 of FIG. 6 and the piecewise expansion profile generation circuitry 624 of FIG. 6 determine the gain input parameters. (Block 1005). In some examples, the gain profile circuitry 621 and the piecewise expansion profile generation circuitry 624 receive parameters of a reference apodization profile, such as gain values, and parameters of a piecewise expansion profile from the gain input parameters 612. In such examples, the parameters of the piecewise expansion profile may include one or more of a number of transducer channels, a number of transducer elements in a gain profile, a number of beamlines, an expansion profile resolution, an interpolation factor, a channel offset value, a reference gain value, an expansion type value, etc.

The number of transducer channels is a value representing a number of transducer channels in the ultrasound system 100. In some examples, the gain input parameters 612 further include a mapping of the transducer channels to a corresponding position in the ultrasound system 100. The number of transducer elements in a gain profile represents the number of gain values for a given gain profile. For example, the number of transducers elements in a gain profile is equal to the number of transducers channels, when the transducer channels have independent gains. The number of beamlines specifies a number of locations that the reference apodization profile is centered on across an image (e.g., the image 236 of FIG. 2). The expansion profile resolution specifies a tolerance of matching the piecewise expansion profile to an ideal expansion profile. The interpolation factor specifies a ratio of the gain value of the reference apodization profile for a positioning of a transducer channel. The channel offset value represents a number of beamlines that are being processed at a given time by the beamforming circuitry 190. The reference gain value is a value that selects a reference apodization profile from a predetermined selection of reference apodization profiles. Alternatively, the reference gain value(s) may be a series of values that form the reference apodization profile. The expansion type value selects a type of expansion or compression of the reference apodization profile across a depth of the image 236.

The reference gain profile circuitry 669 of FIG. 6 determines a reference gain profile. (Block 1010). In some examples, the reference gain profile circuitry 669 has a series of predetermined reference apodization profiles. In some such examples, a user selects the predetermined reference apodization profile by setting the reference gain value. For example, a first reference apodization profile having a constant gain for all transducer channels corresponds to a first reference gain value. A second reference apodization profile having gain values that form a triangular curve corresponds to a second reference gain value. A third reference apodization profile having gain values that form a parabolic curve corresponds to a third reference gain value. In other examples, the reference gain profile circuitry 669 determines a reference apodization profile responsive to gain values or a function of gain values from the gain input parameters 612.

The expansion determination circuitry 672 of FIG. 6 determines a type of expansion profile. (Block 1015). In some examples, the expansion determination circuitry 672 has multiple types of expansion or compression. In some such examples, users select a type of expansion by setting a value of the expansion type value. For example, a first expansion type having a constant expansion factor corresponds to a first expansion type value, and a second expansion type having an exponential expansion factor corresponds to a second expansion type value. In other examples, the expansion determination circuitry 672 determines a type of expansion profile responsive to expansion factors or a function of expansion factors from the gain input parameters 612.

The expansion profile circuitry 675 of FIG. 6 calculates an expansion profile for the type of expansion. (Block 1020). In some examples, the expansion profile circuitry 675 generates an expansion profile as an inverse function of expansion of gain values of the reference apodization profile for an image depth. For example, when the expansion profile is an inverse function, the expansion factor decreases as the image depth increases. In such examples, the expansion factor compresses the reference apodization profile for focus points having relatively small image depths and expands the reference apodization as the image depth of focus points increase. For example, an expansion factor corresponding to the focus point 260 of FIG. 2 compresses the reference apodization profile 445 of FIG. 4B to set gain values of the transducer channels 204, 208, 212, 216, 220, 224, 228, 232 of FIG. 2 using the compressed gain profile 450 of FIG. 4B. In another example, an expansion factor corresponding to the focus point 268 of FIG. 2 expands the reference apodization profile 445 to set gain values of the transducer channels 204, 208, 212, 216, 220, 224, 228, 232 using the expanded gain profile 455 of FIG. 4B.

The segment number determination circuitry 678 of FIG. 6 determines a number of segments. (Block 1025). In some examples, the segment number determination circuitry 678 determines a number of segments of a piecewise expansion profile. In such examples, the gain input parameters 612 specify a specific number of segments to split the expansion profile into. Alternatively, the gain input parameters 612 may specify a maximum number of segments to represent the expansion profile. In such examples, the segment number determination circuitry 678 attempts to use the smallest number of segments to represent the expansion profile using linear segments.

The segment duration determination circuitry 681 of FIG. 6 determines a duration for each of the segments. (Block 1030). In some examples, the segment duration determination circuitry 681 divides the image depth by the number of segments from the segment number determination circuitry 678. In some such examples, the segment duration determination circuitry 681 dynamically divides the image depth across the number of segments. For example, the segment duration determination circuitry 681 increases the segment durations as the image depth increases, such as in the segments 540, 550, 560, 570, 580, 590 of FIG. 5B. In such examples, the segment duration increases as the image depth approaches the maximum image depth 240 of FIG. 2 and the expansion factors begin to settle at a steady state value.

The segment generation circuitry 684 of FIG. 6 determines an initial value of the expansion profile. (Block 1035). In some examples, the segment generation circuitry 684 receives the expansion factor values of the expansion profile 510 of FIG. 5A from the gain profile circuitry 621. In such examples, the segment generation circuitry 684 determines an initial value of the expansion profile to be an expansion factor value at a minimum image depth. In other examples, the segment generation circuitry 684 determines an individual initial value for the segments based on the determined number of segments and the determined segment durations.

The segment generation circuitry 684 divides the expansion profile into the segments based on the durations. (Block 1040). In some examples, the segment generation circuitry 684 splits the expansion factor values of the expansion profile 510 into individual segments based on the segment durations. For example, the segment generation circuitry 684 allocates a first plurality of expansion factor values to a first segment responsive to the first plurality of expansion factor values spanning a first duration. In such examples, the first segment has an initial value and a duration.

The segment fit circuitry 687 of FIG. 6 fits the segments of the expansion profile to linear segments. (Block 1045). In some examples, the segment fit circuitry 687 fits the expansion factor values of the segments to linear segments. In some such examples, the segment fit circuitry 687 generates a linear approximation of the expansion factor values of the segments. In example operation, when the segment fit circuitry 687 is unable to fit the expansion factor values to a linear segment or achieve an acceptable error value the piecewise expansion profile generation circuitry 624 may return to one of Blocks 1025, 1030 to determine an alternative number of segments or alternative segment durations of the previous number of segments.

The segment slope determination circuitry 690 of FIG. 6 determines slopes of the linear segments for the segments of the expansion profile. (Block 1050). In some examples, the segment slope determination circuitry 690 determines a slope of the linear segments determined by the segment fit circuitry 687.

The expansion profile generation circuitry 693 of FIG. 6 generates the PWL expansion profile. (Block 1055). In some examples, the expansion profile generation circuitry 693 forms data structures representing the piecewise expansion profile 530. For example, the expansion profile generation circuitry 693 structures the segment duration of the segments 540, 550, 560, 570, 580, 590 for the piecewise expansion profile 530, the initial value of the piecewise expansion profile 530, and the slope values of the segments of the piecewise expansion profile 530. Control proceeds to return.

Example methods are described with reference to the flowchart illustrated in FIG. 10. However, many other methods of implementing the piecewise beamforming compiler circuitry 606 of FIG. 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 11 is a block diagram of example analog front-end (AFE) circuitry 1100, which is an example of the AFE circuitry 130 of FIG. 1. In the example of FIG. 11, the AFE circuitry 1100 includes first ADC circuitry 1105, second ADC circuitry 1110, beamforming circuitry 1115, beamforming control circuitry 1120, and interface circuitry 1125. The example beamforming circuitry 1115 of FIG. 11 includes first example beamline circuitry 1130 and second example beamline circuitry 1135. The example beamline circuitry 1130 of FIG. 11 includes first example channel beamforming circuitry 1140, second example channel beamforming circuitry 1145, and example combination circuitry 1150. The example channel beamforming circuitry 1140 of FIG. 11 includes example coarse delay circuitry 1155, example fine delay circuitry 1160, and example apodization circuitry 1165. The example channel beamforming circuitry 1145 of FIG. 11 includes example coarse delay circuitry 1170, example fine delay circuitry 1175, and example apodization circuitry 1180.

The ADC circuitry 1105 has a first terminal and a second terminal. The first terminal of the ADC circuitry 1105 is structured to be coupled to one of the transducer channels 140, 150, 160 of FIG. 1 or the transducer channels 204, 208, 212, 216, 220, 224, 228, 232 of FIG. 2. The second terminal of the ADC circuitry 1105 is coupled to the beamforming circuitry 1115. The ADC circuitry 1110 has a first terminal and a second terminal. The first terminal of the ADC circuitry 1110 is structured to be coupled to one of the transducer channels 140, 150, 160 or the transducer channels 204, 208, 212, 216, 220, 224, 228, 232. The second terminal of the ADC circuitry 1110 is coupled to the beamforming circuitry 1115. In the example of FIG. 11, the ADC circuitry 1105, 1110 are an example of the ADC circuitry 180 of FIG. 1. In the example of FIG. 7, the AFE circuitry 1100 has the ADC circuitry 1105, 1110. In other examples, the AFE circuitry 1100 may have any number of instances of the ADC circuitry 1105, 1110 to support any number of transducer channels.

The beamforming circuitry 1115 has a first terminal, a second terminal, a third terminal, a fourth terminal, and a fifth terminal. The first terminal of the beamforming circuitry 1115 is coupled to the ADC circuitry 1105. The second terminal of the beamforming circuitry 1115 is coupled to the ADC circuitry 1110. The third and fourth terminals of the beamforming circuitry 1115 are coupled to the beamforming control circuitry 1120. In some examples, the beamforming circuitry 1115 may have any number of terminals coupled to the beamforming control circuitry 1120 to support any number of transducer channels or configurations. The fifth terminal of the beamforming circuitry 1115 is structured to be coupled to the programmable circuitry 110 of FIG. 1. In some examples, the beamforming circuitry 1115 is coupled to the programmable circuitry 110 by additional interface circuitry, which implements communication protocols to interface between the programmable circuitry 110 and the AFE circuitry 1100. The beamforming circuitry 1115 is an example of the beamforming circuitry 190 of FIG. 1. Another example of the beamforming circuitry 1115 is illustrated and described in connection with FIG. 12, below. Example operations of the beamforming circuitry 1115 are illustrated and described in connection with FIG. 13, below.

The beamforming control circuitry 1120 has a first terminal, a second terminal, and a third terminal. The first and second terminals of the beamforming control circuitry 1120 are coupled to the beamforming circuitry 1115. In the example of FIG. 11, the beamforming control circuitry 1120 may have any number of terminals coupled to the beamforming circuitry 1115 to support any number of transducer channels, delay values, and gain values. The third terminal of the beamforming control circuitry 1120 is coupled to the interface circuitry 1125. An example of the beamforming control circuitry 1120 is further illustrated and described in connection with FIG. 12, below. In some examples, the beamforming control circuitry 1120 is implemented using circuitry resulting from an electronic design automation tool. In such examples, the electronic design automation tool generates a register transfer level design, which instantiates circuitry of the beamforming control circuitry 1120. Example operations of the beamforming control circuitry 1120 are illustrated and described in connection with FIGS. 13, 14, and 15, below.

The interface circuitry 1125 has a first terminal and a second terminal. The first terminal of the interface circuitry 1125 is coupled to the beamforming control circuitry 1120. The second terminal of the interface circuitry 1125 may be coupled to an external data source structured to supply data of the piecewise delay profiles, the reference apodization profile, and the piecewise expansion profile. In such examples, the external data source may be the programmable circuitry 110 or the piecewise beamforming compiler circuitry 606 of FIG. 6.

The beamline circuitry 1130 has a first terminal, a second terminal, a third terminal, a fourth terminal, and a fifth terminal. The first terminal of the beamline circuitry 1130 is coupled to the ADC circuitry 1105. The second terminal of the beamline circuitry 1130 is coupled to the ADC circuitry 1110. The third and fourth terminals of the beamline circuitry 1130 are coupled to the beamforming control circuitry 1120. In some examples, the beamline circuitry 1130 may have any number of terminals coupled to the beamforming control circuitry 1120 to support any number of delay values and gain values. The fifth terminal of the beamline circuitry 1130 is structured to be coupled to the programmable circuitry 110.

The beamline circuitry 1135 is structured similar to the beamline circuitry 1130, which is coupled in parallel with the beamline circuitry 1130 to the ADC circuitry 1105, 1110 and the programmable circuitry 110. The beamline circuitry 1135 is individually coupled to the beamforming control circuitry 1120. In the example of FIG. 11, the beamline circuitry 1130 is structured to process focus points of a first beamline, and the beamline circuitry 1135 is structured to process focus points of a second beamline. For example, the beamline circuitry 1130 performs beamforming operations for focus points of the beamline 244 of FIG. 2, and the beamline circuitry 1135 performs beamforming operations for focus points of the beamline 248. In such examples, the beamforming circuitry 1115 processes focus points of a plurality of beamlines. In the example of FIG. 11, the beamforming circuitry 1115 includes the beamline circuitry 1130, 1135. In other examples, the beamforming circuitry 1115 may include any number of instances of the beamline circuitry 1130, 1135.

The channel beamforming circuitry 1140 has a first terminal, a second terminal, a third terminal, a fourth terminal, and a fifth terminal. The first terminal of the channel beamforming circuitry 1140 is coupled to the ADC circuitry 1105. The second, third, and fourth terminals of the channel beamforming circuitry 1140 are coupled to the beamforming control circuitry 1120, which supplies a first channel coarse delay value (DELAY_{COARSE_CHNL0}), a first channel fine delay value (DELAY_{FINE_CHNL0}), and a first channel gain value (GAIN_{CHNL0}). The first channel coarse and fine delay values form a delay value of the first channel of the AFE circuitry 1100. In some examples, a channel delay value includes a plurality of bits that have a first number of bits representing the coarse delay value and a second number of bits representing the fine delay value. For example, when the delay value is an eleven-bit value, the nine most significant bits represent the coarse delay value and the two least significant bits represent the fine delay value. The fifth terminal of the channel beamforming circuitry 1140 is coupled to the combination circuitry 1150.

The channel beamforming circuitry 1145 has a first terminal, a second terminal, a third terminal, a fourth terminal, and a fifth terminal. The first terminal of the channel beamforming circuitry 1145 is coupled to the ADC circuitry 1110. The second, third, and fourth terminals of the channel beamforming circuitry 1145 are coupled to the beamforming control circuitry 1120, which supplies a second channel coarse delay value (DELAY_{COARSE_CHNLN}), a second channel fine delay value (DELAY_{FINE_CHNLN}), and a second channel gain value (GAIN_{CHNLN}). The fifth terminal of the channel beamforming circuitry 1145 is coupled to the combination circuitry 1150. In the example of FIG. 7, the beamline circuitry 1130 includes the channel beamforming circuitry 1145, in other examples, the beamline circuitry 1130 may include any number of instances of the channel beamforming circuitry 1145 to support any number of transducer channels. For example, the beamline circuitry 1130 includes one-hundred and twenty-eight instances of the channel beamforming circuitry 1140 responsive to the AFE circuitry 1100 being structured to be coupled to one-hundred and twenty-eight transducer channels.

The combination circuitry 1150 has a first terminal, a second terminal, and a third terminal. The first terminal of the combination circuitry 1150 is coupled to the channel beamforming circuitry 1140. The second terminal of the combination circuitry 1150 is coupled to the channel beamforming circuitry 1145. In the example of FIG. 11, the combination circuitry 1150 is coupled to the channel beamforming circuitry 1140, 1145, in other examples, the combination circuitry 1150 may have any number of terminals coupled to any number of beamforming channel circuitry. The third terminal of the combination circuitry 1150 is structured to be coupled to the programmable circuitry 110. In some examples, the combination circuitry 1150 is summation circuitry (also referred to as a summer), which adds values from the channel beamforming circuitry 1140, 1145. Alternatively, the combination circuitry 1150 may implement an alternative form of combining outputs of the channel beamforming circuitry 1140, 1145.

The coarse delay circuitry 1155 has a first terminal, a second terminal, and a third terminal. The first terminal of the coarse delay circuitry 1155 is coupled to the ADC circuitry 1105. The second terminal of the coarse delay circuitry 1155 is coupled to the beamforming control circuitry 1120, which supplies the first channel coarse delay value. The third terminal of the coarse delay circuitry 1155 is coupled to the fine delay circuitry 1160.

The fine delay circuitry 1160 has a first terminal, a second terminal, and a third terminal. The first terminal of the fine delay circuitry 1160 is coupled to the coarse delay circuitry 1155. The second terminal of the fine delay circuitry 1160 is coupled to the beamforming control circuitry 1120, which supplies the first channel fine delay value. The third terminal of the fine delay circuitry 1160 is coupled to the apodization circuitry 1165.

The apodization circuitry 1165 has a first terminal, a second terminal, and a third terminal. The first terminal of the apodization circuitry 1165 is coupled to the fine delay circuitry 1160. The second terminal of the apodization circuitry 1165 is coupled to the beamforming control circuitry 1120, which supplies the first channel gain value. The third terminal of the apodization circuitry 1165 is coupled to the combination circuitry 1150. In the example of FIG. 11, the apodization circuitry 1165 is amplifier circuitry, which is structured to have a configurable gain based on the gain value from the beamforming control circuitry 1120. Alternatively, in other examples, the apodization circuitry 1165 may be implemented using alternative circuitry.

The coarse delay circuitry 1170 has a first terminal, a second terminal, and a third terminal. The first terminal of the coarse delay circuitry 1170 is coupled to the ADC circuitry 1110. The second terminal of the coarse delay circuitry 1170 is coupled to the beamforming control circuitry 1120, which supplies the second channel coarse delay value. The third terminal of the coarse delay circuitry 1170 is coupled to the fine delay circuitry 1175.

The fine delay circuitry 1175 has a first terminal, a second terminal, and a third terminal. The first terminal of the fine delay circuitry 1175 is coupled to the coarse delay circuitry 1170. The second terminal of the fine delay circuitry 1175 is coupled to the beamforming control circuitry 1120, which supplies the second channel fine delay value. The third terminal of the fine delay circuitry 1175 is coupled to the apodization circuitry 1180.

The apodization circuitry 1180 has a first terminal, a second terminal, and a third terminal. The first terminal of the apodization circuitry 1180 is coupled to the fine delay circuitry 1175. The second terminal of the apodization circuitry 1180 is coupled to the beamforming control circuitry 1120, which supplies the second channel gain value. The third terminal of the apodization circuitry 1180 is coupled to the combination circuitry 1150. In the example of FIG. 11, the apodization circuitry 1180 is amplifier circuitry, which is structured to have a configurable gain based on the gain value from the beamforming control circuitry 1120. Alternatively, in other examples, the apodization circuitry 1180 may be implemented using alternative circuitry.

FIG. 12 is a block diagram of an example beamforming system 1200. In the example of FIG. 12, the beamforming system 1200 includes the example beamforming circuitry 1115 of FIG. 11 and example beamforming control circuitry 1204. The example beamforming control circuitry 1204 of FIG. 12 includes example memory circuitry 1208, example cycle clock circuitry 1212, example focus point counter circuitry 1216, example beamline counter circuitry 1220, first example beamline control circuitry 1224, and second example beamline control circuitry 1228. The example beamline control circuitry 1224 of FIG. 12 includes example focus number tracker circuitry 1232, example beamline number tracker circuitry 1236, example segment initialization circuitry 1240, example segment delay duration circuitry 1244, example expansion segment duration circuitry 1248, example segment counter circuitry 1252, first example channel control circuitry 1256, and second example channel control circuitry 1260. The example channel control circuitry 1256 of FIG. 12 includes example initial delay value circuitry 1264, example delay slope circuitry 1268, example delay accumulator circuitry 1272, example initial expansion factor circuitry 1276, example expansion slope circuitry 1280, example expansion accumulator circuitry 1284, and example expansion indexer circuitry 1288. The example memory circuitry 1208 of FIG. 12 includes example reference apodization profile data 1290, example piecewise expansion profile data 1292, and example piecewise delay profile data 1294.

The beamforming circuitry 1115 has a first terminal, a second terminal, a third terminal, a fourth terminal, and a fifth terminal. The first terminal of the beamforming circuitry 1115 may be coupled to the ADC circuitry 1105 of FIG. 11. The second terminal of the beamforming circuitry 1115 may be coupled to the ADC circuitry 1110 of FIG. 11. The third and fourth terminals of the beamforming circuitry 1115 are coupled to the beamforming control circuitry 1204. In some examples, the beamforming circuitry 1115 may have any number of terminals coupled to the beamforming control circuitry 1204 to support any number of transducer channels or configurations. The fifth terminal of the beamforming circuitry 1115 is structured to be coupled to the programmable circuitry 110 of FIG. 1.

The beamforming control circuitry 1204 is coupled to the beamforming circuitry 1115. In some examples, the beamforming control circuitry 1204 is coupled to a data source, which supplies data of the piecewise delay profiles, the reference apodization profile, and the piecewise expansion profile, by the interface circuitry 1125 of FIG. 11. In such examples, the data source is one of the programmable circuitry 110 or the piecewise beamforming compiler circuitry 606 of FIG. 6. The beamforming control circuitry 1204 of FIG. 12 may be instantiated (e.g., creating an instance of, bring into being for any length of time, materialize, implement, etc.) by programmable circuitry such as a Central Processor Unit (CPU) executing first instructions. Also or alternatively, the beamforming control circuitry 1204 of FIG. 12 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 12 may, thus, be instantiated at the same or different times. Some or all of the circuitry of FIG. 12 may be instantiated, for example, in one or more threads executing concurrently on hardware or in series on hardware. Moreover, in some examples, some or all of the circuitry of FIG. 12 may be implemented by microprocessor circuitry executing instructions or FPGA circuitry performing operations to implement one or more virtual machines or containers.

The memory circuitry 1208 has a first terminal, a second terminal, a third terminal, and a fourth terminal. The first terminal of the memory circuitry 1208 is structured to be coupled to the data source, which supplies the piecewise delay profiles, the reference apodization profile, and the piecewise expansion profile. The second, third, and fourth terminals of the memory circuitry 1208 are coupled to the beamline control circuitry 1224. Alternatively, the memory circuitry 1208 may include any number of terminals coupled to the beamline control circuitry 1224, 1228 to support any number of types of access to the data 1290, 1292, 1294.

The cycle clock circuitry 1212 has a terminal coupled to the counter circuitry 1216, 1220 and the beamline control circuitry 1228, 1224. In the example of FIG. 12, the cycle clock circuitry 1212 supplies a beamforming clock signal having a predetermined frequency, which controls the speed at which focus points are processed.

The focus point counter circuitry 1216 has a first terminal and a second terminal. The first terminal of the focus point counter circuitry 1216 is coupled to the cycle clock circuitry 1212, which supplies the beamforming clock signal. The second terminal of the focus point counter circuitry 1216 is coupled to the beamline control circuitry 1224, 1228. In the example of FIG. 12, the focus point counter circuitry 1216 is structured to generate a focus point count responsive to counting cycles of the beamforming clock signal.

The beamline counter circuitry 1220 has a first terminal and a second terminal. The first terminal of the beamline counter circuitry 1220 is coupled to the cycle clock circuitry 1212, which supplies the beamforming clock signal. The second terminal of the beamline counter circuitry 1220 is coupled to the beamline control circuitry 1224, 1228. In the example of FIG. 12, the beamline counter circuitry 1220 is structured to generate a beamline count responsive to dividing a count of cycles of the cycle clock circuitry by the number of focus points in a beamline.

The beamline control circuitry 1224 has a first terminal, a second terminal, a third terminal, a fourth terminal, a fifth terminal, a sixth terminal, and a plurality of output terminals. The first, second, and third terminals of the beamline control circuitry 1224 are coupled to the memory circuitry 1208. The fourth terminal of the beamline control circuitry 1224 is coupled to the cycle clock circuitry 1212, which supplies the beamforming clock signal. The fifth terminal of the beamline control circuitry 1224 is coupled to the focus point counter circuitry 1216, which supplies the focus point count. The sixth terminal of the beamline control circuitry 1224 is coupled to the beamline counter circuitry 1220, which supplies the beamline count. The plurality of output terminals of the beamline control circuitry 1224 are coupled to the beamline circuitry 1130 of FIG. 11, or more generally the beamforming circuitry 1115. In the example of FIG. 12, the beamline control circuitry 1224 is structured to control the beamline circuitry 1130.

The beamline control circuitry 1228 is another instance of the beamline control circuitry 1228, which is coupled in parallel with the beamline control circuitry 1228 to the cycle clock circuitry 1212, the counter circuitry 1216, 1220, and the memory circuitry 1208. The beamline control circuitry 1228 is individually coupled to the beamline circuitry 1135 of FIG. 11. In the example of FIG. 12, the beamline control circuitry 1224 is structured to generate delay values and gain values for focus points of a first beamline and the beamline control circuitry 1228 is structured to generate delay values and gain values for focus points of a second beamline. In the example of FIG. 12, the beamforming control circuitry 1204 includes the beamline control circuitry 1224, 1228. In other examples, the beamforming control circuitry 1204 may include any number of instances of the beamline control circuitry 1224, 1228.

The focus number tracker circuitry 1232 has a first terminal and a second terminal. The first terminal of the focus number tracker circuitry 1232 is coupled to the focus point counter circuitry 1216. The second terminal of the focus number tracker circuitry 1232 is coupled to the segment initialization circuitry 1240.

The beamline number tracker circuitry 1236 has a first terminal and a second terminal. The first terminal of the beamline number tracker circuitry 1236 is coupled to the beamline counter circuitry 1220. The second terminal of the beamline number tracker circuitry 1236 is coupled to the segment initialization circuitry 1240.

The segment initialization circuitry 1240 has a first terminal, a second terminal, a third terminal, a fourth terminal, a fifth terminal, a sixth terminal, a seventh terminal, an eighth terminal, a ninth terminal, a tenth terminal, and an eleventh terminal. The first terminal of the segment initialization circuitry 1240 is coupled to the focus number tracker circuitry 1232. The second terminal of the segment initialization circuitry 1240 is coupled to the beamline number tracker circuitry 1236. The third and fourth terminals of the segment initialization circuitry 1240 are coupled to the memory circuitry 1208, which supplies the data 1292, 1294. The fifth terminal of the segment initialization circuitry 1240 is coupled to the segment delay duration circuitry 1244. The sixth terminal of the segment initialization circuitry 1240 is coupled to the expansion segment duration circuitry 1248. The seventh terminal of the segment initialization circuitry 1240 is coupled to the segment counter circuitry 1252. The eighth, ninth, tenth, and eleventh terminals of the segment initialization circuitry 1240 are coupled to the channel control circuitry 1256.

The segment delay duration circuitry 1244 has a first terminal and a second terminal. The first terminal of the segment delay duration circuitry 1244 is coupled to the segment initialization circuitry 1240. The second terminal of the segment delay duration circuitry 1244 is coupled to the segment counter circuitry 1252.

The segment expansion duration circuitry 1248 has a first terminal and a second terminal. The first terminal of the expansion segment duration circuitry 1248 is coupled to the segment initialization circuitry 1240. The second terminal of the expansion segment duration circuitry 1248 is coupled to the segment counter circuitry 1252.

The segment counter circuitry 1252 has a first terminal, a second terminal, a third terminal, and a fourth terminal. The first terminal of the segment counter circuitry 1252 is coupled to the cycle clock circuitry 1212, which supplies the beamforming clock signal. The second terminal of the segment counter circuitry 1252 is coupled to the segment initialization circuitry 1240. The third terminal of the segment counter circuitry 1252 is coupled to the segment delay duration circuitry 1244. The fourth terminal of the segment counter circuitry 1252 is coupled to the expansion segment duration circuitry 1248.

The channel control circuitry 1256 has a first terminal, a second terminal, a third terminal, a fourth terminal, a fifth terminal, a sixth terminal, a seventh terminal, an eighth terminal, a ninth terminal, and a tenth terminal. The first terminal of the channel control circuitry is coupled to the cycle clock circuitry 1212, which supplies the beamforming clock signal. The second terminal of the channel control circuitry 1256 is coupled to the memory circuitry 1208, which supplies the reference apodization profile data 1290. The third, fourth, fifth, sixth, and seventh terminals of the channel control circuitry 1256 are coupled to the segment initialization circuitry 1240. The eighth, ninth, and tenth terminals of the channel control circuitry 1256 are coupled to the channel beamforming circuitry 1140 of FIG. 11. In some examples, the channel control circuitry 1256 has any number of terminals coupled to the channel beamforming circuitry 1140.

The channel control circuitry 1260 is another instance of the channel control circuitry 1256, which is coupled in parallel with the channel control circuitry 1256 to the cycle clock circuitry 1212, the memory circuitry 1208, and the segment initialization circuitry 1240. The channel control circuitry 1260 is individually coupled to the channel beamforming circuitry 1145 of FIG. 11. In the example of FIG. 12, the channel control circuitry 1256 is structured to generate delay values and gain values for a first transducer channel and the channel control circuitry 1260 is structured to generate delay values and gain values a second transducer channel. In the example of FIG. 12, the beamline control circuitry 1224 includes the channel control circuitry 1256, 1260. In other examples, the beamline control circuitry 1224 may include any number of instances of the channel control circuitry 1256, 1260.

The initial delay value circuitry 1264 has a first terminal and a second terminal. The first terminal of the initial delay value circuitry 1264 is coupled to the segment initialization circuitry 1240. The second terminal of the initial delay value circuitry 1264 is coupled to the delay accumulator circuitry 1272.

The delay slope circuitry 1268 has a first terminal and a second terminal. The first terminal of the delay slope circuitry 1268 is coupled to the segment initialization circuitry 1240. The second terminal of the delay slope circuitry 1268 is coupled to the delay accumulator circuitry 1272.

The delay accumulator circuitry 1272 has a first terminal, a second terminal, a third terminal, a fourth terminal, and a fifth terminal. The first terminal of the delay accumulator circuitry 1272 is couples to the cycle clock circuitry 1212, which supplies the beamforming clock signal. The second terminal of the delay accumulator circuitry 1272 is coupled to the initial delay value circuitry 1264. The third terminal of the delay accumulator circuitry 1272 is coupled to the delay slope circuitry 1268. The fourth terminal of the delay accumulator circuitry 1272 is coupled to the coarse delay circuitry 1155 of FIG. 11. The fifth terminal of the delay accumulator circuitry 1272 is coupled to the fine delay circuitry 1160 of FIG. 11.

The initial expansion factor circuitry 1276 has a first terminal and a second terminal. The first terminal of the initial expansion factor circuitry 1276 is coupled to the segment initialization circuitry 1240. The second terminal of the initial expansion factor circuitry 1276 is coupled to the expansion accumulator circuitry 1284.

The expansion slope circuitry 1280 has a first terminal and a second terminal. The first terminal of the expansion slope circuitry 1280 is coupled to the segment initialization circuitry 1240. The second terminal of the expansion slope circuitry 1280 is coupled to the expansion accumulator circuitry 1284.

The expansion accumulator circuitry 1284 has a first terminal, a second terminal, a third terminal, and a fourth terminal. The first terminal of the expansion accumulator circuitry 1284 is coupled to the cycle clock circuitry 1212, which supplies the beamforming clock signal. The second terminal of the expansion accumulator circuitry 1284 is coupled to the initial expansion factor circuitry 1276. The third terminal of the expansion accumulator circuitry 1284 is coupled to the expansion slope circuitry 1280. The fourth terminal of the expansion accumulator circuitry 1284 is coupled to the expansion indexer circuitry 1288.

The expansion indexer circuitry 1288 has a first terminal, a second terminal, and a third terminal. The first terminal of the expansion indexer circuitry 1288 is coupled to the memory circuitry 1208, which supplies the reference apodization profile data 1290. The second terminal of the expansion indexer circuitry 1288 is coupled to the expansion accumulator circuitry 1284. The third terminal of the expansion indexer circuitry 1288 is coupled to the apodization circuitry 1165 of FIG. 11.

The reference apodization profile data 1290 is coupled to the expansion indexer circuitry 1288. The reference apodization profile data 1290 is a portion of memory that stores gains of the reference apodization profile 445 of FIG. 4B. In some examples, the piecewise beamforming compiler circuitry 606 of FIG. 6 generates the reference apodization profile data 1290 responsive to performing the operations 1000 of FIG. 10, or more generally the operations 700 of FIG. 7.

The piecewise expansion profile data 1292 is coupled to the segment initialization circuitry 1240. The piecewise expansion profile data 1292 is a portion of memory that stores gains of the piecewise expansion profile 530 of FIG. 5B. In some examples, the piecewise beamforming compiler circuitry 606 generates the piecewise expansion profile data 1292 responsive to performing the operations 1000 of FIG. 10, or more generally the operations 700 of FIG. 7.

The piecewise delay profile data 1294 is coupled to the segment initialization circuitry 1240. The piecewise delay profile data 1294 is a portion of memory that stores gains of the piecewise delay profiles 330, 335, 340 of FIG. 3B. In some examples, the piecewise beamforming compiler circuitry 606 generates the piecewise delay profile data 1294 responsive to performing the operations 800, 900 of FIGS. 8 and 9, or more generally the operations 700 of FIG. 7.

FIG. 13 is a flowchart representative of example machine-readable instructions or example operations 1300 that may be at least one of executed, instantiated, or performed using an example programmable circuitry implementation of the beamforming circuitry 190, 1115 of FIGS. 1, 11, and 12 and the beamforming control circuitry 1120, 1204 of FIGS. 11 and 12 or more generally the ultrasound system 100 of FIG. 1. The example operations 1300 of FIG. 13 begin at Block 1305, at which the beamforming control circuitry 1120, 1204 receives PWL delay profiles, a PWL expansion profile, and a reference apodization profile. (Block 1305). In some examples, the piecewise beamforming compiler circuitry 606 of FIG. 6 generates the reference apodization profile data 1290 of FIG. 12, the piecewise expansion profile data 1292 of FIG. 12, and the piecewise delay profile data 1294 of FIG. 12 responsive to performing the operations 800, 900, 1000 of FIGS. 8, 9, and 10, or more generally the operations 700 of FIG. 7. In such examples, the piecewise beamforming compiler circuitry 606 supplies the data 1290, 1292, 1294 to one of the programmable circuitry 110 of FIG. 1, the memory circuitry 1208 of FIG. 12, or an external data source. In example operation, the interface circuitry 1125 of FIG. 11 facilitates a transfer of the data 1290, 1292, 1294 to the memory circuitry 1208. In some example operations, the interface circuitry 1125 communicates with one of the piecewise beamforming compiler circuitry 606, the programmable circuitry 110, or an external data source to receive the data 1290, 1292, 1294.

The beamline number tracker circuitry 1236 of FIG. 12 selects a beamline. (Block 1310). In some examples, the beamline number tracker circuitry 1236 determines a beamline for the beamline control circuitry 1224 of FIG. 12 to process responsive to the beamline count from the beamline counter circuitry 1220. The beamline count represents a number of beamlines that the beamforming control circuitry 1204 has processed. In some example operations, when the beamforming control circuitry 1204 includes a plurality of instances of the beamline control circuitry 1224, the beamline number tracker circuitry 1236 adjusts the beamline count based on a number of beamlines being processed in parallel. For example, when the beamforming control circuitry 1204 includes four instances of the beamline control circuitry 1224, which are structured to process four beamlines in parallel, the beamline number tracker circuitry 1236 multiplies the beamline count by four. In such examples, the beamline number tracker circuitry 1236 of other instances of the beamline control circuitry 1224 multiple the beamline count by four and add an offset value to prevent multiple instances of the beamline control circuitry 1224 from processing the same beamline.

At least one of the transducer channels 140, 150, 160 of FIG. 1 begin transmitting. (Block 1315). In some examples, the transmitter circuitry 120 of FIG. 1 excites one or more of the transducer channels 140, 150, 160 responsive to supplying an excitation signal to the one or more of the transducer channels 140, 150, 160. The transducer channels 140, 150, 160 are structured to generate a signal to traverse a medium positioned in front of the transducer channels 140, 150, 160. In example operations, the transmitter circuitry 120 controls the frequency and amplitude of the excitation signal to generate a specific signal to traverse the medium. In some example operations, the transmitter circuitry 120 determines which of the transducer channels 140, 150, 160 to excite responsive to the beamline count of the beamline counter circuitry 1220. For example, the transmitter circuitry 120 excites the transducer channels 216, 220 of FIG. 2 responsive to the beamline count representing the beamline 252 of FIG. 2 is being processed by the beamforming circuitry 190, 1115.

The transducer channels 140, 150, 160 receive reflections of the transmitted signal. (Block 1320). In some examples, signals from the one or more of the transducer channels 140, 150, 160 generate reflections as the signals traverse through the medium. In such examples, the reflections of the transmitted signals have characteristics specific to the composition of the portion of the medium that reflects the transmitted signal. The transducer channels 140, 150, 160 generate analog signals representing the reflected signals responsive to the reflections of the transmitted signals exciting the transducer channels 140, 150, 160. In example operations, the transmitter circuitry 120 includes switch circuitry between the transducer channels 140, 150, 160. In such example operations, the transmitter circuitry 120 positions the switches to supply the excitation signal to selected one(s) of the transducer channels 140, 150, 160. After transmitting the excitation signal, the transmitter circuitry 120 positions the switches to supply the reflected signals from the transducer channels 140, 150, 160 to the AFE circuitry 130, 1100.

The ADC circuitry 180, 1105, 1110 of FIGS. 1 and 11 generate digital signals representing the received analog signals. (Block 1325). In some examples, the ADC circuitry 180, 1105, 1110 generate digital signals responsive to converting the analog signals from the transducer channels 140, 150, 160. In some examples, the AFE circuitry 130, 1100 of FIGS. 1 and 11 include additional instances of the ADC circuitry 180, 1105, 1110 to support additional transducer channels. For example, the AFE circuitry 130, 1100 includes thirty-two instances of the ADC circuitry 180, 1105, 1110 to support thirty-two transducer channels. In such examples, the AFE circuitry 130, 1100 generates thirty-two digital signals to represent thirty-two analog signals. The ADC circuitry 180, 1105, 1110 supply the digital signals to the beamforming circuitry 190, 1115 for beamforming.

The focus number tracker circuitry 1232 of FIG. 12 selects a focus point on the beamline. (Block 1330). In some examples, the focus number tracker circuitry 1232 determines a focus point for the beamline control circuitry 1224 to process for a given cycle of the beamforming clock signal responsive to the focus point count from the focus point counter circuitry 1216 of FIG. 12. The focus point count represents a number of focus points along a beamline that the beamforming control circuitry 1204 has processed. Also, the focus point of the focus number tracker circuitry 1232 corresponds to an image depth to be processed along the beamline of the beamline number tracker circuitry 1236. In some example operations, when the beamforming control circuitry 1204 includes a plurality of instances of the beamline control circuitry 1224, the focus number tracker circuitry 1232 is the same for all beamlines being processed.

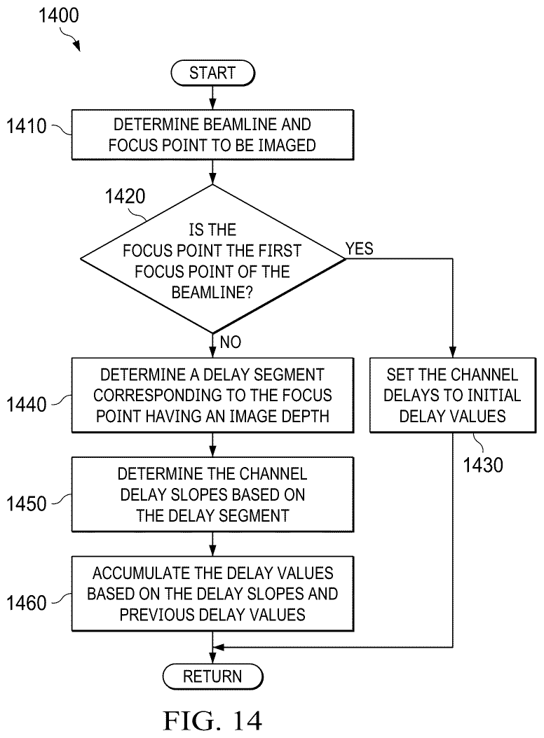

The channel control circuitry 1256, 1260 of FIG. 12 computes channel delays for the focus point on the beamline. (Operations 1400 of FIG. 14, below). In some examples, the channel control circuitry 1256, 1260 determine channel delay values for the selected focus point on the selected beamline based on the piecewise delay profile data 1294. In such examples, the beamline control circuitry 1224, 1228 include an instance of the channel control circuitry 1256 for each transducer channel. For example, the beamline control circuitry 1224 includes thirty-two instances of the channel control circuitry 1256 responsive to the beamforming circuitry 190, 1115 supporting thirty-two transducer channels.

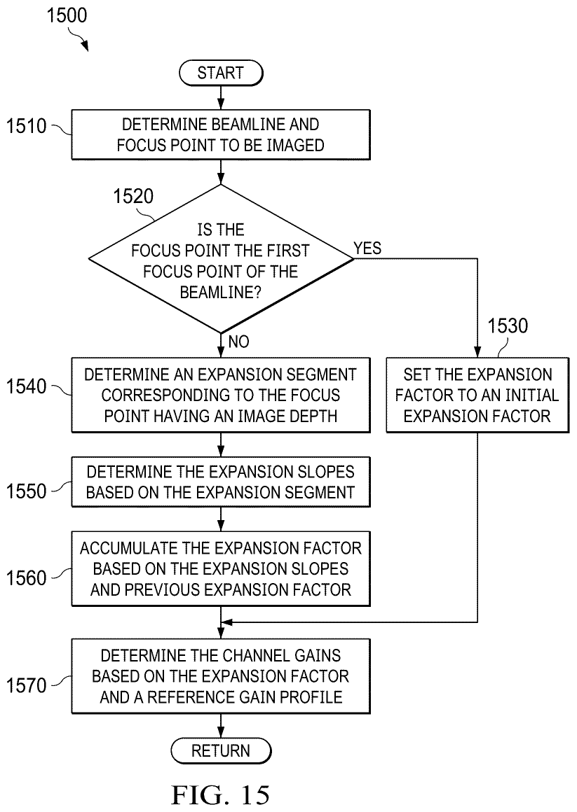

The channel control circuitry 1256, 1260 of FIG. 12 computes channel gains for the focus point on the beamline. (Operations 1500 of FIG. 15, below). In some examples, the channel control circuitry 1256, 1260 determine channel gain values for the selected focus point on the selected beamline based on the reference apodization profile data 1290 and the piecewise expansion profile data 1292. In such examples, the channel control circuitry 1256 determines the first channel gain value and the channel control circuitry 1260 determines the second channel gain value.

The delay circuitry 1155, 1160, 1170, 1175 of FIGS. 11 and 12 delay the digital signals by the channel delays for the depth of the focus point. (Block 1335). In some examples, the coarse delay circuitry 1155, 1170 receive digital signals from the ADC circuitry 1105, 1110 and coarse delay values from the beamforming control circuitry 1120, 1204. The coarse delay values are a first number of bits of the delay value. In such examples, the fine delay circuitry 1160, 1175 receive the delayed digital signals from the coarse delay circuitry 1155, 1170 and fine delay values from the beamforming control circuitry 1120, 1204. The fine delay values are a second number of bits of the delay value. In example operations, the coarse delay circuitry 1155, 1170 delay the digital signals based on the coarse delay values and the fine delay circuitry 1160, 1175 delay the digital signals based on the fine delay values.

The apodization circuitry 1165, 1180 of FIGS. 11 and 12 amplify the delayed signals by the channel gains for the depth of the focus point. (Block 1340). In some examples, the apodization circuitry 1165, 1180 receives the delayed digital signals from the fine delay circuitry 1160, 1175 and the gain values from the beamforming control circuitry 1120, 1204. In example operations, the apodization circuitry 1165, 1180 is an amplifier structured to amplify the delayed digital signals by the gain values.

The combination circuitry 1150 of FIGS. 11 and 12 combines the amplified and delayed signals of the transducer channels. (Block 1345). In some examples, the combination circuitry 1150 receives the amplified digital signals from the apodization circuitry 1165, 1180. In such examples, the combination circuitry 1150 determines a value of the selected focus point on the selected beamline by combining the values of the amplified digital signals.

The beamline circuitry 1130, 1135 of FIGS. 11 and 12 supply the combined value of the focus point to programmable circuitry. (Block 1350). In some examples, the beamline circuitry 1130, 1135 supplies determined values of the focus point for the selected beamline(s). In such examples, the beamline circuitry 1130, 1135 supplies the determined values to the programmable circuitry 110.

The focus point counter circuitry 1216 of FIG. 12 determines if all of the focus points of the selected beamline have been processed. (Block 1355). In some examples, the focus point counter circuitry 1216 continues to increment the focus point count until the focus point count is equal to the number of focus points per beamline. In such examples, the focus point counter circuitry 1216 resets the focus point count when the focus point count is equal to the number of focus points.

If the focus point counter circuitry 1216 determines that not all of the focus points of the selected beamline have been processed (e.g., Block 1355 returns a result of NO), the focus number tracker circuitry 1232 selects an unprocessed focus point on the beamline. (Block 1360). In some examples, the focus point counter circuitry 1216 increments the focus point count based on the beamforming clock signal from the cycle clock circuitry 1212. Control proceeds to return to the operations 1400.

If the focus point counter circuitry 1216 determines that all of the focus points of the selected beamline have been processed (e.g., Block 1355 returns a result of YES), the beamline counter circuitry 1220 of FIG. 12 determines if all beamlines have been processed. (Block 1365). In some examples, the beamline counter circuitry 1220 continues to increment the beamline count until the beamline count is equal to the number of beamlines in the image 236.

If the beamline counter circuitry 1220 determines that not all of the beamlines have been processed (e.g., Block 1365 returns a result of NO), the beamline number tracker circuitry 1236 selects an unprocessed beamline. (Block 1370). In some examples, the beamline counter circuitry 1220 increments the beamline count based on the beamforming clock signal from the cycle clock circuitry 1212. Control proceeds to return to Block 1315.

If the beamline counter circuitry 1220 determines that all of the beamlines have been processed (e.g., Block 1365 returns a result of YES), the beamline number tracker circuitry 1236 begins a new frame. (Block 1375). In some examples, the beamline counter circuitry 1220 resets the beamline count when the focus beamline count is equal to the number of beamlines in the image 236 divided by the number of parallel beamlines being processed by the beamforming circuitry 190, 1115. Control proceeds to return to Block 1310.

Example methods are described with reference to the flowchart illustrated in FIG. 13. However, many other methods of implementing the beamforming circuitry 190, 1115 of FIGS. 1, 11, and 12 and the beamforming control circuitry 1120, 1204 of FIGS. 11 and 12 or more generally the ultrasound system 100 of FIG. 1 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 14 is a flowchart representative of example machine-readable instructions or example operations 1400 that may be at least one of executed, instantiated, or performed using an example programmable circuitry implementation of the beamforming control circuitry 1120, 1204 of FIGS. 11 and 12 to determine delay values from the piecewise delay profiles 330, 335, 340 of FIG. 3B. The example operations 1400 of FIG. 14 begin at Block 1410, at which the focus number tracker circuitry 1232 of FIG. 12 and the beamline number tracker circuitry 1236 of FIG. 12 determines beamline and focus point to be imaged. (Block 1410). In some examples, the number tracker circuitry 1232, 1236 tracks the focus point and beamlines selected in Blocks 1310, 1330, 1360, 1370 of FIG. 13. In such examples, the number tracker circuitry 1232, 1236 determine the selected focus point and beamline based on the focus point count of the focus point counter circuitry 1216 of FIG. 12 and the beamline count of the beamline counter circuitry 1220 of FIG. 12.

The segment initialization circuitry 1240 of FIG. 12 determines if the focus point is the first focus point of the beamline. (Block 1420). In some examples, the segment initialization circuitry 1240 determines that the selected focus point is a first focus point of the selected beamline responsive to the selected focus point of the focus number tracker circuitry 1232 having an initial value.

If the segment initialization circuitry 1240 determines that the focus point is the first focus point of the beamline (e.g., Block 1420 returns a result of YES), the initial delay value circuitry 1264 of FIG. 12 sets the channel delay to initial delay values. (Block 1430). In example operations, the segment initialization circuitry 1240 determines initial delay values for the selected beamline based on the piecewise delay profile data 1294. In some examples, the segment initialization circuitry 1240 stores the initial delay value in the initial delay value circuitry 1264. The initial delay value circuitry 1264 sets an initial value of the delay accumulator circuitry 1272 to set the delay values to the initial delay value.

If the segment initialization circuitry 1240 determines that the focus point is not the first focus point of the beamline (e.g., Block 1420 returns a result of NO), the segment counter circuitry 1252 of FIG. 12 determines a delay segment corresponding to the focus point having an image depth. (Block 1440). In example operations, the segment initialization circuitry 1240 determines the segment duration based on the piecewise delay profile data 1294. In some examples, the segment initialization circuitry 1240 stores the segment duration of the segment containing the selected focus point in the segment delay duration circuitry 1244 of FIG. 12. In such examples, the segment counter circuitry 1252 determines a delay segment count based on cycles of the beamforming clock signal. The segment initialization circuitry 1240 initializes a subsequent segment of the delay profiles responsive to the segment counter circuitry 1252 generating a delay segment count that is equal to the value of the segment delay duration circuitry 1244.

The delay slope circuitry 1268 of FIG. 12 determines the channel delay slopes based on the delay segment. (Block 1450). In example operations, the segment initialization circuitry 1240 determines the slope values of a segment based on the piecewise delay profile data 1294. In some examples, the segment initialization circuitry 1240 stores the slope values of the segment containing the selected focus point in the delay slope circuitry 1268.

The delay accumulator circuitry 1272 of FIG. 12 accumulates the delay values based on the delay slopes and previous delay values. (Block 1460). In example operations, the delay accumulator circuitry 1272 receives the initial delay value from the initial delay value circuitry 1264 and the slope value from the delay slope circuitry 1268. In some examples, the delay accumulator circuitry 1272 generates the delay values of a focus point responsive to adding the slope value to a previous delay value. In such examples, the delay accumulator circuitry 1272 sets the first delay value of the selected beamline equal to the initial delay value. Also, the delay accumulator circuitry 1272 may use subsequent slope values as the segment initialization circuitry 1240 updates the delay slope circuitry 1268. Control proceeds to return.

Example methods are described with reference to the flowchart illustrated in FIG. 14. However, many other methods of implementing the beamforming control circuitry 1120, 1204 of FIGS. 1, 11, and 12 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 15 is a flowchart representative of example machine-readable instructions or example operations 1500 that may be at least one of executed, instantiated, or performed using an example programmable circuitry implementation of the beamforming control circuitry 1120, 1204 of FIGS. 1, 11, and 12 to determine gain values from the piecewise expansion profile 530 of FIG. 5B. The example operations 1500 of FIG. 15 begin at Block 1510, at which the focus number tracker circuitry 1232 of FIG. 12 and the beamline number tracker circuitry 1236 of FIG. 12 determines a beamline and focus point to be imaged. (Block 1510). In some examples, the number tracker circuitry 1232, 1236 tracks the focus point and beamlines selected in Blocks 1310, 1330, 1360, 1370 of FIG. 13. In such examples, the number tracker circuitry 1232, 1236 determine the selected focus point and beamline based on the focus point count of the focus point counter circuitry 1216 of FIG. 12 and the beamline count of the beamline counter circuitry 1220 of FIG. 12.

The segment initialization circuitry 1240 of FIG. 12 determines if the focus point is the first focus point of the beamline. (Block 1520). In some examples, the segment initialization circuitry 1240 determines that the selected focus point is a first focus point of the selected beamline responsive to the selected focus point of the focus number tracker circuitry 1232 having an initial value.

If the segment initialization circuitry 1240 determines that the focus point is the first focus point of the beamline (e.g., Block 1520 returns a result of YES), the initial expansion factor circuitry 1276 of FIG. 12 sets the expansion factor to an initial expansion factor. (Block 1530). In example operations, the segment initialization circuitry 1240 determines an initial expansion factor for the selected beamline based on the piecewise expansion profile data 1292 of FIG. 12. In some examples, the segment initialization circuitry 1240 stores the initial expansion factor in the initial expansion factor circuitry 1276 of FIG. 12. The initial expansion factor circuitry 1276 sets an initial value of the expansion accumulator circuitry 1284 to set the expansion factor to the initial expansion factor.

If the segment initialization circuitry 1240 determines that the focus point not the first focus point of the beamline (e.g., Block 1520 returns a result of NO), the segment counter circuitry 1252 of FIG. 12 determines an expansion segment corresponding to the focus point having an image depth. (Block 1540). In example operations, the segment initialization circuitry 1240 determines the segment duration based on the piecewise expansion profile data 1292. In some examples, the segment initialization circuitry 1240 stores the segment duration of the segment containing the selected focus point in the expansion segment duration circuitry 1248 of FIG. 12. In such examples, the segment counter circuitry 1252 determines an expansion segment count based on cycles of the beamforming clock signal. The segment initialization circuitry 1240 initializes a subsequent segment of the expansion profile responsive to the segment counter circuitry 1252 generating an expansion segment count that is equal to the value of the expansion segment duration circuitry 1248.

The expansion slope circuitry 1280 of FIG. 12 determines the expansion slopes based on the expansion segment. (Block 1550). In example operations, the segment initialization circuitry 1240 determines the slope values of a segment based on the piecewise expansion profile data 1292. In some examples, the segment initialization circuitry 1240 stores the slope values of the segment containing the selected focus point in the expansion slope circuitry 1280.

The expansion accumulator circuitry 1284 of FIG. 12 accumulates the expansion factor based on the expansion slopes and previous expansion factor. (Block 1560). In example operations, the expansion accumulator circuitry 1284 receives the initial expansion factor from the initial expansion factor circuitry 1276 and the slope value from the expansion slope circuitry 1280. In some examples, the expansion accumulator circuitry 1284 generates the expansion factor of a focus point responsive to adding the slope value to a previous expansion factor. In such examples, the expansion accumulator circuitry 1284 sets the first expansion factor of the selected beamline equal to the initial expansion factor. Also, the expansion accumulator circuitry 1284 may use subsequent slope values as the segment initialization circuitry 1240 updates the expansion slope circuitry 1280.

The expansion indexer circuitry 1288 of FIG. 12 determines the channel gains based on the expansion factor and a reference gain profile. (Block 1570). In example operations, the expansion indexer circuitry 1288 determines a gain value of a channel based on the expansion factor, the transducer channel corresponding to the channel control circuitry 1256, and the reference apodization profile data 1290 of FIG. 12. In some examples, the reference apodization profile data 1290 includes all possible gain values of channels for a given expansion factor and the selected reference gain profile. In such examples, the expansion indexer circuitry 1288 determines the gain value of a channel by looking up the gain value for the transducer channel and expansion factor. Control proceeds to return to Block 1335 of FIG. 13.

Example methods are described with reference to the flowchart illustrated in FIG. 15. However, many other methods of implementing the beamforming control circuitry 1120, 1204 of FIGS. 1, 11, and 12 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 16 is a block diagram of an example programmable circuitry platform 1600 structured to one or a combination of execute or instantiate one or more of the example machine-readable instructions or the example operations of FIGS. 7, 8, 9, 10, 13, 14 and/or 15. The programmable circuitry platform 1600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1600 of the illustrated example includes programmable circuitry 1612. The programmable circuitry 1612 of the illustrated example is hardware. For example, the programmable circuitry 1612 can be implemented by one or more integrated circuits, logic circuits, FPGAs, microprocessors, CPUs, GPUs, DSPs, or microcontrollers from any desired family or manufacturer. The programmable circuitry 1612 may be implemented by one or more semiconductor based (e.g., silicon based) devices. In this example, the programmable circuitry 1612 implements one or more of the piecewise beamforming compiler circuitry 606 of FIG. 6 or the beamforming control circuitry 1120, 1204 of FIGS. 11 and 12.

The programmable circuitry 1612 of the illustrated example includes a local memory 1613 (e.g., a cache, registers, etc.). The programmable circuitry 1612 of the illustrated example is in communication with main memory 1614, 1616, which includes a volatile memory 1614 and a non-volatile memory 1616, by a bus 1618. The volatile memory 1614 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1616 may be implemented by one or a combination of flash memory or any other desired type of memory device. Access to the main memory 1614, 1616 of the illustrated example is controlled by a memory controller 1617. In some examples, the memory controller 1617 may be implemented by one or more integrated circuits, logic circuits, microcontrollers from any desired family or manufacturer, or any other type of circuitry to manage the flow of data going to and from the main memory 1614, 1616.

The programmable circuitry platform 1600 of the illustrated example also includes interface circuitry 1620. The interface circuitry 1620 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1622 are connected to the interface circuitry 1620. The input device(s) 1622 permit(s) a user (e.g., a human user, a machine user, etc.) to enter one of or a combination of data or commands into the programmable circuitry 1612. The input device(s) 1622 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1624 are also connected to the interface circuitry 1620 of the illustrated example. The output device(s) 1624 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1620 of the illustrated example, thus, includes one of or a combination of a graphics driver card, a graphics driver chip, or graphics processor circuitry such as a GPU.

The interface circuitry 1620 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1600 of the illustrated example also includes one or more mass storage discs or devices 1628 to store one or more of firmware, software, or data. Examples of such mass storage discs or devices 1628 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1632, which may be implemented by the machine-readable instructions of FIGS. 7, 8, 9, 10, 13, 14 and/or 15, may be stored in one of or a combination of the mass storage device 1628, in the volatile memory 1614, in the non-volatile memory 1616, or on at least one non-transitory computer readable storage medium such as a CD or DVD which may be removable.

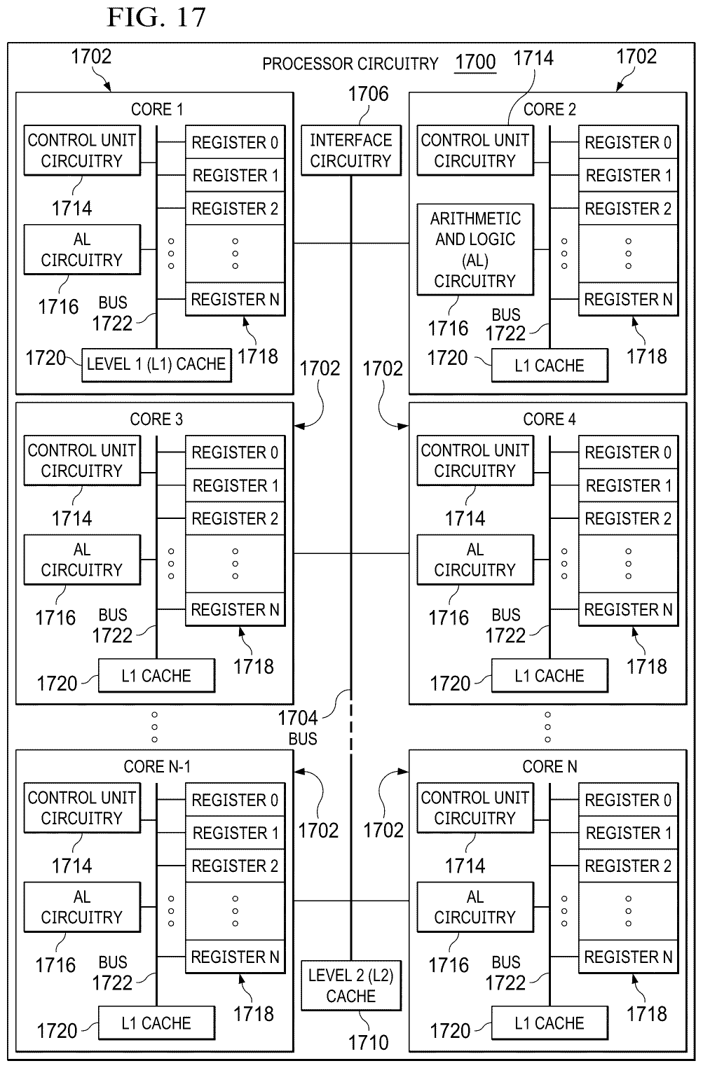

FIG. 17 is a block diagram of an example implementation of the programmable circuitry 1612 of FIG. 16. In this example, the programmable circuitry 1612 of FIG. 16 is implemented by a microprocessor 1700. For example, the microprocessor 1700 may be a general-purpose microprocessor (e.g., general-purpose microprocessor circuitry). The microprocessor 1700 executes some or all of the machine-readable instructions of the flowcharts of FIGS. [Flowcharts] to effectively instantiate the circuitry of FIG. 6, 11, or 12 as logic circuits to perform operations corresponding to those machine-readable instructions. In some such examples, the circuitry of FIG. 6, 11, or 12 is instantiated by the hardware circuits of the microprocessor 1700 in combination with the machine-readable instructions. For example, the microprocessor 1700 may be implemented by multi-core hardware circuitry such as a CPU, a DSP, a GPU, an XPU, etc. Although it may include any number of example cores 1702 (e.g., 1 core), the microprocessor 1700 of this example is a multi-core semiconductor device including N cores. The cores 1702 of the microprocessor 1700 may operate independently or may cooperate to execute machine-readable instructions. For example, machine code corresponding to a firmware program, an embedded software program, or a software program may be executed by one of the cores 1702 or may be executed by multiple ones of the cores 1702 at the same or different times. In some examples, the machine code corresponding to the firmware program, the embedded software program, or the software program is split into threads and executed in parallel by two or more of the cores 1702. The software program may correspond to a portion or all of the machine-readable instructions or operations represented by the flowcharts of FIGS. FIGS. 7, 8, 9, 10, 13, 14 and/or 15.

The cores 1702 may communicate by a first example bus 1704. In some examples, the first bus 1704 may be implemented by a communication bus to effectuate communication associated with one(s) of the cores 1702. For example, the first bus 1704 may be implemented by at least one of an Inter-Integrated Circuit (I2C) bus, a Serial Peripheral Interface (SPI) bus, a PCI bus, or a PCIe bus. Also or alternatively, the first bus 1704 may be implemented by any other type of computing or electrical bus. The cores 1702 may obtain data, instructions, and signals from one or more external devices by example interface circuitry 1706. The cores 1702 may output data, instructions, and signals to the one or more external devices by the interface circuitry 1706. Although the cores 1702 of this example include example local memory 1720 (e.g., Level 1 (L1) cache that may be split into an L1 data cache and an L1 instruction cache), the microprocessor 1700 also includes example shared memory 1710 that may be shared by the cores (e.g., Level 2 (L2 cache)) for high-speed access to data and instructions. Data and instructions may be transferred (e.g., shared) by one of or a combination of writing to or reading from the shared memory 1710. The local memory 1720 of each of the cores 1702 and the shared memory 1710 may be part of a hierarchy of storage devices including multiple levels of cache memory and the main memory (e.g., the main memory 1614, 1616 of FIG. 16). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1702 may be referred to as a CPU, DSP, GPU, etc., or any other type of hardware circuitry. Each core 1702 includes control unit circuitry 1714, arithmetic and logic (AL) circuitry (sometimes referred to as an ALU) 1716, a plurality of registers 1718, the local memory 1720, and a second example bus 1722. Other structures may be present. For example, each core 1702 may include vector unit circuitry, single instruction multiple data (SIMD) unit circuitry, load/store unit (LSU) circuitry, branch/jump unit circuitry, floating-point unit (FPU) circuitry, etc. The control unit circuitry 1714 includes semiconductor-based circuits structured to control (e.g., coordinate) data movement within the corresponding core 1702. The AL circuitry 1716 includes semiconductor-based circuits structured to perform one or more mathematic or logic operations on the data within the corresponding core 1702. The AL circuitry 1716 of some examples performs integer-based operations. In other examples, the AL circuitry 1716 also performs floating-point operations. In yet other examples, the AL circuitry 1716 may include first AL circuitry that performs integer-based operations and second AL circuitry that performs floating-point operations. In some examples, the AL circuitry 1716 may be referred to as an Arithmetic Logic Unit (ALU).

The registers 1718 are semiconductor-based structures to store data and instructions such as results of one or more of the operations performed by the AL circuitry 1716 of the corresponding core 1702. For example, the registers 1718 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1718 may be arranged in a bank as shown in FIG. 17. Alternatively, the registers 1718 may be organized in any other arrangement, format, or structure, such as by being distributed throughout the core 1702 to shorten access time. The second bus 1722 may be implemented by at least one of an I2C bus, a SPI bus, a PCI bus, or a PCIe bus.

Each core 1702 or, more generally, the microprocessor 1700 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1700 is a semiconductor device fabricated to include many transistors interconnected to implement the structures described above in one or more integrated circuits (ICs) contained in one or more packages.

The microprocessor 1700 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those discussed herein. A GPU, DSP, or other programmable device can also be an accelerator. Accelerators may be on-board the microprocessor 1700, in the same chip package as the microprocessor 1700, or in one or more separate packages from the microprocessor 1700.

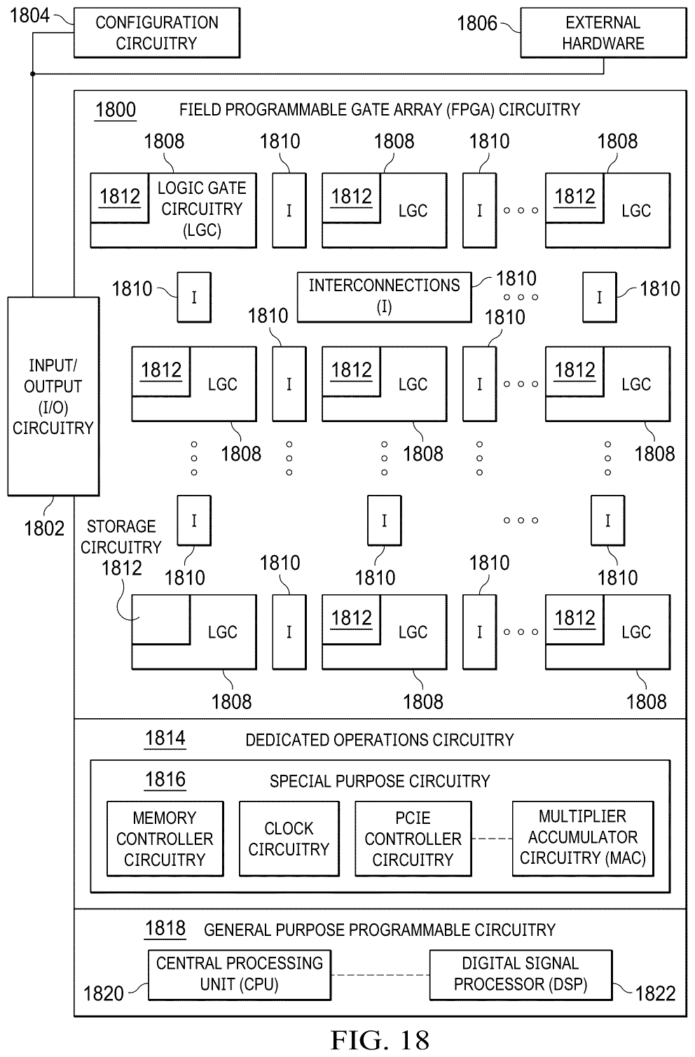

FIG. 18 is a block diagram of another example implementation of the programmable circuitry 1612 of FIG. 16. In this example, the programmable circuitry 1612 is implemented by FPGA circuitry 1800. For example, the FPGA circuitry 1800 may be implemented by an FPGA. The FPGA circuitry 1800 can be used, for example, to perform operations that could otherwise be performed by the example microprocessor 1700 of FIG. 17 executing corresponding machine-readable instructions. However, once configured, the FPGA circuitry 1800 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1700 of FIG. 17 described above (which is a general purpose device that may be programmed to execute some or all of the machine-readable instructions represented by the flowchart(s) of FIGS. FIGS. 7, 8, 9, 10, 13, 14 and/or 15 but whose interconnections and logic circuitry are fixed once fabricated), the FPGA circuitry 1800 of the example of FIG. 18 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIGS. FIGS. 7, 8, 9, 10, 13, 14 and/or 15. In particular, the FPGA circuitry 1800 may be thought of as an array of logic gates, interconnections, and switches. The switches can be programmed to change how the logic gates are interconnected by the interconnections, effectively forming one or more dedicated logic circuits (unless and until the FPGA circuitry 1800 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. FIGS. 7, 8, 9, 10, 13, 14 and/or 15. As such, the FPGA circuitry 1800 may be at least one of configured or structured to effectively instantiate some or all of the operations/functions corresponding to the machine-readable instructions of the flowchart(s) of FIGS. FIGS. 7, 8, 9, 10, 13, 14 and/or 15 as dedicated logic circuits to perform the operations/functions corresponding to those software instructions in a dedicated manner analogous to an ASIC. Therefore, the FPGA circuitry 1800 may perform the operations/functions corresponding to the some or all of the machine-readable instructions of FIGS. FIGS. 7, 8, 9, 10, 13, 14 and/or 15 faster than the general-purpose microprocessor can execute the same.

In the example of FIG. 18, the FPGA circuitry 1800 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1800 of FIG. 18 may at least one of access or load the binary file to cause the FPGA circuitry 1800 of FIG. 18 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1800 of FIG. 18 to at least one of configure or structure the FPGA circuitry 1800 of FIG. 18, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1800 of FIG. 18 may at least one of access or load the binary file to cause the FPGA circuitry 1800 of FIG. 18 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1800 of FIG. 18 to at least one of configure or structure the FPGA circuitry 1800 of FIG. 18, or portion(s) thereof.

The FPGA circuitry 1800 of FIG. 18, includes example input/output (I/O) circuitry 1802 to at least one of obtain or output data to/from at least one of example configuration circuitry 1804 or external hardware 1806. For example, the configuration circuitry 1804 may be implemented by interface circuitry that may obtain a binary file, which may be implemented by one or more of a bit stream, data, or machine-readable instructions, to configure the FPGA circuitry 1800, or portion(s) thereof. In some such examples, the configuration circuitry 1804 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1806 may be implemented by external hardware circuitry. For example, the external hardware 1806 may be implemented by the microprocessor 1700 of FIG. 17.

The FPGA circuitry 1800 also includes an array of example logic gate circuitry 1808, a plurality of example configurable interconnections 1810, and example storage circuitry 1812. The logic gate circuitry 1808 and the configurable interconnections 1810 are configurable to instantiate one or more operations/functions that may correspond to at least some of the machine-readable instructions of FIGS. FIGS. 7, 8, 9, 10, 13, 14 and/or 15 and/or other desired operations. The logic gate circuitry 1808 shown in FIG. 18 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1808 to enable configuration of one of or a combination of the electrical structures or the logic gates to form circuits to perform desired operations/functions. The logic gate circuitry 1808 may include other electrical structures such as look-up tables (LUTs), registers (e.g., flip-flops or latches), multiplexers, etc.

The configurable interconnections 1810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1808 to program desired logic circuits.

The storage circuitry 1812 of the illustrated example is structured to store result(s) of the one or more of the operations performed by corresponding logic gates. The storage circuitry 1812 may be implemented by registers or the like. In the illustrated example, the storage circuitry 1812 is distributed amongst the logic gate circuitry 1808 to facilitate access and increase execution speed.

The example FPGA circuitry 1800 of FIG. 18 also includes example dedicated operations circuitry 1814. In this example, the dedicated operations circuitry 1814 includes special purpose circuitry 1816 that may be invoked to implement commonly used functions to avoid the need to program those functions in the field. Examples of such special purpose circuitry 1816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1800 may also include example general purpose programmable circuitry 1818 such as an example CPU 1820 or an example DSP 1822. Other general purpose programmable circuitry 1818 may also or alternatively be present such as a GPU, an XPU, etc., that can be programmed to perform other operations.

Although FIGS. 17 and 18 illustrate two example implementations of the programmable circuitry 1612 of FIG. 16, many other approaches are contemplated. For example, FPGA circuitry may include an on-board CPU, such as one or more of the example CPU 1820 of FIG. 17. Therefore, the programmable circuitry 1612 of FIG. 16 may also be implemented by combining at least the example microprocessor 1700 of FIG. 17 and the example FPGA circuitry 1800 of FIG. 18. In some such hybrid examples, one or more cores 1702 of FIG. 17 may execute a first portion of the machine-readable instructions represented by the flowchart(s) of FIGS. 7, 8, 9, 10, 13, 14 and/or 15 to perform first operation(s)/function(s), the FPGA circuitry 1800 of FIG. 18 may be at least one of configured or structured to perform second operation(s)/function(s) corresponding to a second portion of the machine-readable instructions represented by the flowcharts of FIGS. 7, 8, 9, 10, 13, 14 and/or 15, and/or an ASIC may be at least one of configured or structured to perform third operation(s)/function(s) corresponding to a third portion of the machine-readable instructions represented by the flowcharts of FIGS. 7, 8, 9, 10, 13, 14 and/or 15.

Some or all of the circuitry of FIG. 6, 11, or 12 may, thus, be instantiated at the same or different times. For example, same and/or different portion(s) of the microprocessor 1700 of FIG. 17 may be programmed to execute portion(s) of machine-readable instructions at the same and/or different times. In some examples, same and/or different portion(s) of the FPGA circuitry 1800 of FIG. 18 may be at least one of configured or structured to perform operations/functions corresponding to portion(s) of machine-readable instructions at the same and/or different times.

In some examples, some or all of the circuitry of FIG. 6, 11, or 12 may be instantiated, for example, in one or more threads executing concurrently and/or in series. For example, the microprocessor 1700 of FIG. 17 may execute machine-readable instructions in one or more threads executing concurrently and/or in series. In some examples, the FPGA circuitry 1800 of FIG. 18 may be at least one of configured or structured to carry out operations/functions concurrently and/or in series. Moreover, in some examples, some or all of the circuitry of FIG. 6, 11, or 12 may be implemented within one or more virtual machines or containers executing on the microprocessor 1700 of FIG. 17.

In some examples, the programmable circuitry 1612 of FIG. 16 may be in one or more packages. For example, at least one of the microprocessor 1700 of FIG. 17 or the FPGA circuitry 1800 of FIG. 18 may be in one or more packages. In some examples, an XPU may be implemented by the programmable circuitry 1612 of FIG. 16, which may be in one or more packages. For example, the XPU may include a CPU (e.g., the microprocessor 1700 of FIG. 17, the CPU 1820 of FIG. 18, etc.) in one package, a DSP (e.g., the DSP 1822 of FIG. 18) in another package, a GPU in yet another package, and an FPGA (e.g., the FPGA circuitry 1800 of FIG. 18) in still yet another package.

While an example manner of implementing the piecewise beamforming compiler circuitry 606 is illustrated in FIG. 6, one or more of the elements, processes, or devices illustrated in FIG. 6 may be combined, divided, re-arranged, omitted, eliminated, or implemented in any other way. Further, the piecewise beamforming compiler circuitry 606, may be implemented by hardware alone or by hardware in combination with software and firmware. Thus, for example, any of the components of the example piecewise beamforming compiler circuitry 606, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example piecewise beamforming compiler circuitry 606 may include one or more elements, processes, or devices in addition to, or instead of, those illustrated in FIG. 6, or may include more than one of any or all of the illustrated elements, processes and devices.

While an example manner of implementing the beamforming control circuitry 1120, 1204 are illustrated in FIGS. 11 and 12, one or more of the elements, processes, or devices illustrated in FIG. 12 may be combined, divided, re-arranged, omitted, eliminated, or implemented in any other way. Further, the beamforming control circuitry 1120, 1204, may be implemented by hardware alone or by hardware in combination with software and firmware. Thus, for example, any of the components of the example beamforming control circuitry 1120, 1204, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example beamforming control circuitry 1120, 1204 may include one or more elements, processes, or devices in addition to, or instead of, those illustrated in FIG. 12, or may include more than one of any or all of the illustrated elements, processes and devices.

Flowchart(s) representative of example machine-readable instructions, which may be executed by programmable circuitry to at least one of implement or instantiate the piecewise beamforming compiler circuitry 606 of FIG. 6 or the beamforming control circuitry 1120, 1204 of FIGS. 11 and 12 or representative of example operations which may be performed by programmable circuitry to at least one of implement or instantiate the piecewise beamforming compiler circuitry 606 of FIG. 6 or the beamforming control circuitry 1120, 1204 of FIGS. 11 and 12, are shown in FIGS. FIGS. 7, 8, 9, 10, 13, 14 and/or 15. The machine-readable instructions may be one or more executable programs or portion(s) of one or more executable programs for execution by programmable circuitry such as the programmable circuitry 1612 shown in the example processor platform 1600 discussed below in connection with FIG. 16 and may be one or more function(s) or portion(s) of functions to be performed by the example programmable circuitry (e.g., an FPGA) discussed below in connection with FIG. 17 or 18. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. FIGS. 7, 8, 9, 10, 13, 14 and/or 15, many other methods of implementing the example FIGS. 7, 8, 9, 10, 13, 14 and/or 15 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 7, 8, 9, 10, 13, 14 and/or 15 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B.

As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
at least one memory; and
programmable circuitry coupled to the memory and configured to execute machine readable instructions in the at least one memory to cause the programmable circuitry to at least:
determine beamforming delay profiles for a plurality of channels, the beamforming delay profiles including delay values corresponding to a distance from a channel for a beamline;
split the beamforming delay profiles into a plurality of segments;
fit the plurality of segments of the beamforming delay profiles to linear segments;
generate piece-wise beamforming delay profiles including initial values of the beamforming delay profiles, slopes of the linear segments of the plurality of segments, and durations of the plurality of segments; and
store the piece-wise beamforming delay profiles for beamforming.

2. The apparatus of claim 1, wherein the programmable circuitry is further configured to:
determine a reference gain profile, the reference gain profile including gain values corresponding to a distance of a focus point from the channel for the beamline; and
determine an expansion profile for the reference gain profile.

3. The apparatus of claim 2, wherein the plurality of segments are a first plurality of segments, and the programmable circuitry is further configured to:
split the expansion profile into a second plurality of segments; and
fit the second plurality of segments of the expansion profile to linear segments.

4. The apparatus of claim 3, wherein the programmable circuitry is further configured to:
generate a piece-wise expansion profile including an initial value of the expansion profile, slopes of the linear segments of the second plurality of segments, and durations of the second plurality of segments; and
store the piece-wise expansion profile and the reference gain profile for beamforming.

5. The apparatus of claim 4, wherein the expansion profile characterizes at least one of a compression or expansion of gain values of the reference gain profile per depth of the focus point in an image.

6. The apparatus of claim 1, wherein the piece-wise beamforming delay profiles include a piece-wise delay profile for each channel of the plurality of channels and each beamline of a plurality of beamlines that form an image, the piece-wise delay profile for each channel and each beamline having a slope for each segment of the plurality of segments and an initial value.

7. The apparatus of claim 1, wherein the programmable circuitry is further configured to supply the piece-wise beamforming delay profiles, a reference gain profile, and a piece-wise expansion profile to beamforming circuitry.

8. An apparatus comprising:
at least one memory; and
programmable circuitry coupled to the memory and configured to execute machine readable instructions in the at least one memory to cause the programmable circuitry to:
determine a reference gain profile, the reference gain profile including gain values corresponding to a distance of a focus point from a channel;
determine an expansion profile for the reference gain profile;
split the expansion profile into a plurality of segments;
fit the plurality of segments of the expansion profile to linear segments;
generate a piece-wise expansion profile including an initial value of the expansion profile, slopes of the linear segments of the plurality of segments, and durations of the plurality of segments; and
store the piece-wise expansion profile for beamforming.

9. The apparatus of claim 8, wherein the programmable circuitry is further configured to determine beamforming delay profiles for a plurality of channels, the beamforming delay profiles including delay values corresponding to the distance from the channel for a beam line.

10. The apparatus of claim 9, wherein the plurality of segments are a first plurality of segments, and the programmable circuitry is further configured to:
split the beamforming delay profiles into a second plurality of segments; and
fit the second plurality of segments of the beamforming delay profiles to linear segments.

11. The apparatus of claim 10, wherein the programmable circuitry is further configured to:
generate piece-wise beamforming delay profiles including initial values of the beamforming delay profiles, slopes of the linear segments of the second plurality of segments, and durations of the plurality of segments; and
store the piece-wise beamforming delay profiles for beamforming.

12. The apparatus of claim 11, wherein the piece-wise beamforming delay profiles include a piece-wise delay profile for each channel of the plurality of channels and each beamline of a plurality of beamlines that form an image, the piece-wise delay profile for each channel and each beamline having a slope for each segment of the plurality of segments and an initial value.

13. The apparatus of claim 8, wherein the expansion profile characterizes at least one of a compression or expansion of gain values of the reference gain profile per depth of the focus point in an image.

14. The apparatus of claim 8, wherein the programmable circuitry is further configured to supply piece-wise beamforming delay profiles, the reference gain profile, and the piece-wise expansion profile to beamforming circuitry.

15. At least one non-transitory machine-readable storage medium comprising instructions that, when executed, cause programmable circuitry to at least:
generate piece-wise delay profiles including initial values of beamforming delay profiles, slopes of first linear segments of a first plurality of segments of the beamforming delay profiles, and durations of the first plurality of segments, the beamforming delay profiles including delay values corresponding to a distance from a channel for a beam line; and
generate a piece-wise expansion profile including an initial value of an expansion profile of a reference gain profile, slopes of second linear segments of a second plurality of segments of the expansion profile, and durations of the second plurality of segments, the reference gain profile including gain values corresponding to a distance of a focus point from a channel.

16. The at least one non-transitory computer readable storage medium of claim 15, wherein the instructions are to cause the programmable circuitry to determine beamforming delay profiles for a plurality of channels, the beamforming delay profiles including delay values corresponding to the distance from the channel for a beam line.

17. The at least one non-transitory computer readable storage medium of claim 16, wherein the instructions are to cause the programmable circuitry to:
split the beamforming delay profiles into the first plurality of segments; and
fit the first plurality of segments of the beamforming delay profiles to the first linear segments.

18. The at least one non-transitory computer readable storage medium of claim 15, wherein the instructions are to cause the programmable circuitry to:
determine a reference gain profile, the reference gain profile including gain values corresponding to a distance of a focus point from the channel; and
determine an expansion profile for the reference gain profile.

19. The at least one non-transitory computer readable storage medium of claim 18, wherein the instructions are to cause the programmable circuitry to:
split the expansion profile into the second plurality of segments; and
fit the second plurality of segments of the expansion profile to the second linear segments.

20. The at least one non-transitory computer readable storage medium of claim 15, wherein the instructions are to cause the programmable circuitry to store the piece-wise delay profiles, the reference gain profile, and the piece-wise expansion profile for beamforming.
